(19) United States
(12) Patent Application Publication
(10) Pub. No.: US 2024/0125872 A1
(43) Pub. Date: Apr. 18, 2024

(54) MAGNETORESISTIVE SENSOR

(71) Applicant: Analog Devices International Unlimited Company, Limerick (IE)

(72) Inventors: Fernando Franco, Limerick (IE); Jan Kubik, Limerick (IE); Jochen Schmitt, Biedenkopf (DE); Stephen O'Brien, Clarina (IE)

(21) Appl. No.: 18/475,135

(22) Filed: Sep. 26, 2023

Related U.S. Application Data
(60) Provisional application No. 63/378,204, filed on Oct. 3, 2022.

(51) Int. Cl. G01R 33/09

(52) U.S. Cl. CPC G01R 33/091; G01R 33/093; G01R 33/098; G01R 33/025

(57) ABSTRACT

The present disclosure provides a magnetoresistive (xMR) sensor that has enhanced immunity to the presence of a magnetic cross field by using a combination of differential biasing on the sensing layers of the sensing elements, sensing elements having different sensitivities, and different reference magnetization directions. The xMR sensor comprises two or more arrays of sensing elements, wherein each array comprises a plurality of sensing elements. The sensing elements within each array may be arranged in pairs, wherein the sensor elements within each pair have sensing layers that are magnetically biased in antiparallel directions. The sensing elements within each array are also provided with different respective sensitivities. The sensing elements having the lowest sensitivity are provided with a reference layer magnetised in a first direction, and the sensing elements in the remaining arrays are provided with a reference layer magnetised in a direction that is antiparallel to the first direction.

### FIELD OF INVENTION

The present disclosure relates to a magnetoresistive sensor. In particular, the present disclosure relates to a magnetoresistive sensor having enhanced immunity to the presence of a magnetic cross field.

### BACKGROUND

Magnetoresistive (xMR) sensors are highly sensitive magnetic field sensors that provide the measurement of a single field component. As illustrated by FIGS. 1A-B, a typical xMR stack 1, such as a giant magnetoresistive (GMR) or tunnel magnetoresistive (TMR) stack, is typically composed of an antiferromagnet layer 10 and a reference structure 12, which are configured to set a fixed magnetization direction that does not rotate within the operating range of the sensor. This fixed magnetization direction defines the sensing axis of the whole sensing device.

The sensing layer 14 (also referred to as the free layer) is a ferromagnetic layer that is free to rotate under the presence of an external magnetic field. The output of the sensing device is given by the angle between the sensing layer 14 and the reference structure 12, from which information about the magnetic field strength of an external magnetic field can be derived. A minimum and maximum resistance state is obtained when the sensing layer 14 and the reference structure 12 have parallel and antiparallel saturation states respectively.

### SUMMARY

The present disclosure provides a magnetoresistive (xMR) sensor that has enhanced immunity to the presence of a magnetic cross field, that is, a magnetic field applied in plane in a direction orthogonal to the sensing direction of the sensor, which can adversely affect the sensitivity of the sensor. The present disclosure seeks to achieve this by using a combination of a differential biasing on the sensing layers of the sensing elements, sensing elements having different sensitivities (for example, using different aspect ratios) and different reference magnetization directions. The xMR sensor comprises two or more arrays of sensing elements, wherein each array comprises a plurality of sensing elements. As one example, the sensing elements within each array may be arranged in pairs, wherein the sensor elements within each pair have sensing layers that are magnetically biased in antiparallel directions, for example, through an exchange bias provided by an additional antiferromagnetic layer, to thereby provide the differential biasing. The sensing elements within each array are also provided with different respective sensitivities, which may be achieved through one or more of different aspect ratios, different sensing layer compositions, different soft pinning on the sensing layer of each array and an additional external biasing on one or more of the arrays. The sensing elements having the lowest sensitivity are provided with a reference layer that is magnetised in a first direction, this first direction defining the sensing direction of the xMR sensor. The sensing elements in the remaining arrays are then provided with a reference layer that is magnetised in a direction that is antiparallel to the first direction. By building an xMR sensor with sensing elements that have different sensitivity levels and different tolerances to cross-fields, an xMR sensor with enhanced immunity to cross-fields is provided.

A first aspect of the present disclosure provides a magnetoresistive field sensor system, comprising one or more magnetoresistive field sensors, each magnetoresistive field sensor comprising a first sensor array of magnetoresistive sensing elements having a first sensitivity, wherein each of the magnetoresistive elements in the first array comprise a sensing layer to which a first biasing field is applied, and a reference structure magnetised in a first reference magnetisation direction, and at least a second sensor array of magnetoresistive sensing elements having a second sensitivity, the second sensitivity being higher than the first sensitivity, wherein each of the magnetoresistive elements in the second array comprise a sensing layer to which a second biasing field is applied, and a reference structure magnetised in a second reference magnetisation direction, the second reference magnetisation direction being opposite to the first reference magnetisation direction.

As such, the present disclosure provides a magnetoresistive sensor that combines differential biasing, with sensing elements having different sensitivities and opposing reference directions, to thereby reduce the effect of magnetic cross-fields. By using arrays of sensors with different sensitivities and opposite reference directions, the resulting magnetoresistive sensor provides a wider and more robust range of operation than those that use only differential biasing to reduce the effect of cross-fields. As such, the present invention provides an improved magnetoresistive sensor with enhanced immunity to cross-fields.

In some arrangements, the first sensor array may comprise magnetoresistive elements having a first aspect ratio to thereby provide the first sensitivity, and the second sensor array may comprise magnetoresistive elements having a second aspect ratio to thereby provide the second sensitivity. That is to say, the size of the sensing elements is varied to provide different sensitivity levels, with sensors having a higher aspect ratio providing a lower sensitivity. It will however be appreciated that the sensitivity of the sensing elements may be varied through other means, for example, by using sensing elements with different xMR stack arrangements, by applying different biasing fields to the sensing layer to provide different amounts of soft pinning, or by applying an additional external biasing field to one or more of the sensing elements (e.g., through a field produced by an electromagnet or a permanent magnet) to thereby vary the sensitivity.

In some arrangements, the first sensor array may comprise a first number of magnetoresistive sensing elements and the second sensor array may comprise a second number of magnetoresistive sensing elements. Preferably, the first number of magnetoresistive sensing elements may be different to the second number of magnetoresistive sensing elements. That is to say, each sensor array can have a different number of sensing elements, for example, depending on the respective sensitivity of said sensing elements.

In some cases, the first and second number of sensing elements may be determined by a respective weighted value, wherein each weighted value is indicative of the percentage of a sensor output provided by the respective array. For example, sensing elements with the highest sensitivity are generally more susceptible to cross-field and will therefore represent a lower percentage of the magnetic sensor output. As such, the sensor array comprising sensing elements with the higher sensitivity may comprise a smaller number of sensing elements than the sensor array(s) comprising sensing elements with a relatively lower sensitivity.

In some arrangements, the first and second biasing field may be induced by differential sensing layer bias. For example, the first and second sensor arrays may comprise respective pairs of magnetoresistive sensing elements with softly pinned antiparallel sensing layers. In such arrangements, the sensing layers of the respective pairs of magnetoresistive sensing elements may be softly pinned by an antiferromagnetic layer.

In other arrangements, the first and second biasing fields may be induced by one or more permanent magnets or an electromagnet.

In some arrangements, each magnetoresistive field sensor may further comprise a third array of magnetoresistive sensing elements having a third sensitivity, the third sensitivity being higher than the second sensitivity, wherein each of the magnetoresistive elements in the third array comprise a sensing layer to which a third biasing field is applied, and a reference structure magnetised in the second reference magnetisation direction. It will also be appreciated that each magnetoresistive field sensor may comprise any number of sensor arrays having varying levels of sensitivities and biasing fields applied thereto.

In some arrangements, the third sensor array may comprise magnetoresistive elements having a third aspect ratio to thereby provide the third sensitivity.

In some arrangements, the third biasing field may be induced by differential sensing layer bias. For example, the third sensor array may comprise respective pairs of magnetoresistive sensing elements with softly pinned antiparallel sensing layers. In such cases, the sensing layers of the respective pairs of magnetoresistive sensing elements may be softly pinned by an antiferromagnetic layer.

In other arrangements, the third biasing field may be induced by one or more permanent magnets or an electromagnet.

In some arrangements, the first reference magnetisation direction may define the sensing direction of the one or more magnetoresistive field sensors.

In some arrangements, the magnetoresistive field sensor system may comprise a first set of magnetoresistive field sensors connected in a first Wheatstone bridge arrangement.

Additionally, the system may further comprise a second set of magnetoresistive field sensors connected in a second Wheatstone bridge arrangement, wherein the second Wheatstone bridge arrangement is rotated 90° relative to the first Wheatstone bridge arrangement.

The magnetoresistive sensing elements may be tunnel magnetoresistive sensing elements or giant magnetoresistive sensing elements.

### BRIEF DESCRIPTION OF THE DRAWINGS

The present disclosure will now be described by way of example only with reference to the accompanying drawings in which:

FIG. 1A illustrates an example of a typical magnetoresistive sensor stack;

FIG. 1B illustrates an example of the direction of magnetization in the layers of a linearized sensor element;

FIG. 2 illustrates an example of the shape and sensing direction of a typical magnetoresistive element

FIGS. 3A-B further illustrate the impact of a cross field on a typical magnetoresistive sensing device;

FIGS. 4A-C illustrate the impact of a cross field on a typical magnetoresistive sensing device in the presence of a biasing field;

FIGS. 5A-B illustrate an example of a pair of magnetoresistive sensor elements in accordance with the present disclosure;

FIG. 6A further illustrates an example of a magnetoresistive sensor element in accordance with the present disclosure;

FIG. 6B illustrates the effect of the structure of the sensing layer on the biasing field;

FIGS. 7A-C illustrate the impact of a cross field on magnetoresistive sensing device of a first sensitivity in accordance with the present disclosure;

FIGS. 8A-C illustrate the impact of a cross field on magnetoresistive sensing device of a second sensitivity in accordance with the present disclosure;

FIGS. 9A-C illustrate the impact of a cross field on magnetoresistive sensing device of a third sensitivity in accordance with the present disclosure;

FIG. 10 illustrates the impact of a cross field on magnetoresistive sensing devices of varying sensitivities;

FIGS. 11A-C illustrate an example of sensor optimization in accordance with the present disclosure;

FIGS. 12A-B illustrate an impact of a cross field on an optimised magnetoresistive sensor in accordance with the present disclosure;

FIG. 13 illustrates a first example of a pair of sensing elements with differential sensing layer bias;

FIG. 14 illustrates a second example of a pair of sensing elements with differential sensing layer bias;

FIG. 15 illustrates an example magnetic sensor in accordance with the present disclosure;

FIG. 16 illustrates a further example magnetic sensor in accordance with the present disclosure;

FIG. 17 illustrates a further example magnetic sensor in accordance with the present disclosure;

FIG. 18 further illustrates an example magnetic sensor in accordance with the present disclosure;

FIG. 19 further illustrates an example of magnetic sensor in accordance with the present disclosure;

FIG. 20 illustrates an example method of fabricating a magnetic sensor in accordance with the present disclosure;

FIG. 21 illustrates a further example method of fabricating a magnetic sensor in accordance with the present disclosure;

FIGS. 22A-D illustrate part of a method of fabricating a magnetic sensor in accordance with the present disclosure;

FIGS. 23A-E illustrate a further part of a method of fabricating a magnetic sensor in accordance with the present disclosure;

FIGS. 24A-D illustrate a further part of a method of fabricating a magnetic sensor in accordance with the present disclosure;

FIGS. 25A-B illustrate a further part of a method of fabricating a magnetic sensor in accordance with the present disclosure;

FIGS. 26A-G illustrate a further part of a method of fabricating a magnetic sensor in accordance with the present disclosure;

FIGS. 27A-G illustrate a further part of a method of fabricating a magnetic sensor in accordance with present disclosure;

FIGS. 28A-C illustrate a further part of a method of fabricating and magnetic sensor in accordance with the present disclosure.

### DETAILED DESCRIPTION

Magnetoresistive (xMR) sensors are highly sensitive magnetic field sensors that provide the measurement of a single field component. Such magnetic sensing devices are particularly useful for sensing and measuring the magnetic field that is generated by a flow of electric current, and can thus be used to sense and measure the electric currents themselves. Such magnetic sensing devices can therefore be applied to a variety of different applications, such as automotive applications, medical applications, industrial control applications, consumer applications, and a host of other applications where current sensing is required.

As discussed above, a typical xMR stack used in xMR sensing devices will comprise a reference structure and a sensing layer, wherein the output of the sensing device is given by the angle between the sensing layer and the reference structure.

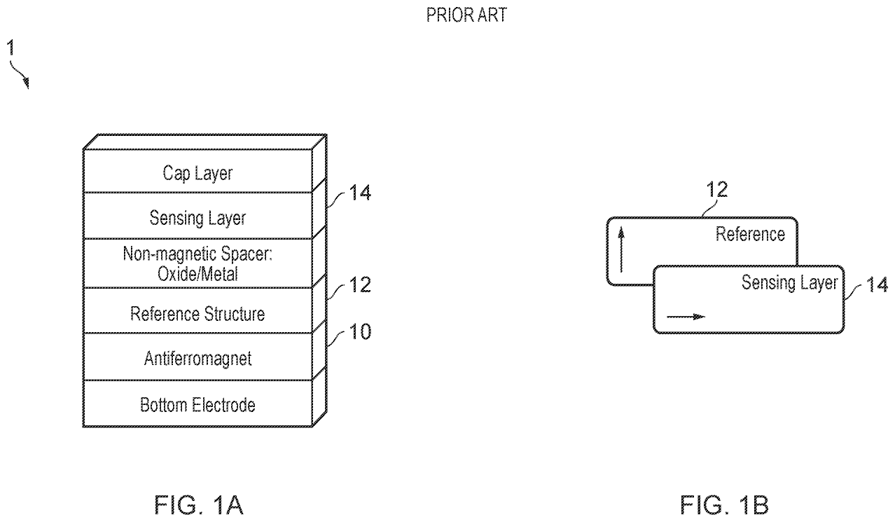

Usually, a linear response between the saturation states is obtained when the magnetization direction of the sensing layer 14 and the reference structure 12 are perpendicular or almost perpendicular in the absence of an external field, as shown in FIG. 1B. The magnetization direction of the reference structure 12 is defined by an exchange bias coupling (unidirectional coupling). Linearization can then be achieved (i.e., so that the magnetization direction of the sensing layer 14 is perpendicular to that of the reference structure 12)) in a number of different ways. As one example, linearization may be achieved through the shape anisotropy of the sensing layer 14 (uniaxial linearization). In this respect, the shape anisotropy is determined by the geometry of the sensing elements. For example, a high shape anisotropy is obtained in sensing elements having a high aspect ratio, wherein the length of the sensing element is substantially greater than the width of the sensing element. That is to say, a sensing element that is much longer than its width or height will automatically magnetize in the direction of its length without needing to apply an external magnetic field being required. As another example, linearization may be achieved by applying a biasing field perpendicular to the sensing axis (unidirectional linearization), for example, using a magnetic field produced by a permanent magnet.

In the presence of a magnetic cross field (i.e., a magnetic field applied in plane of the magnetoresistive sensor film in a direction perpendicular to the sensing axis of the sensor), the sensitivity of a standalone sensor changes. The nature of the change in sensitivity will depend on the linearization strategy. For example, for uniaxial linearization, the sensor sensitivity decreases as the absolute cross field increases. For unidirectional linearization, the sensitivity will decrease if the sum of the bias field and cross field increases. In either case, this can result in uncertainty of sensor measurements when a cross magnetic field is present.

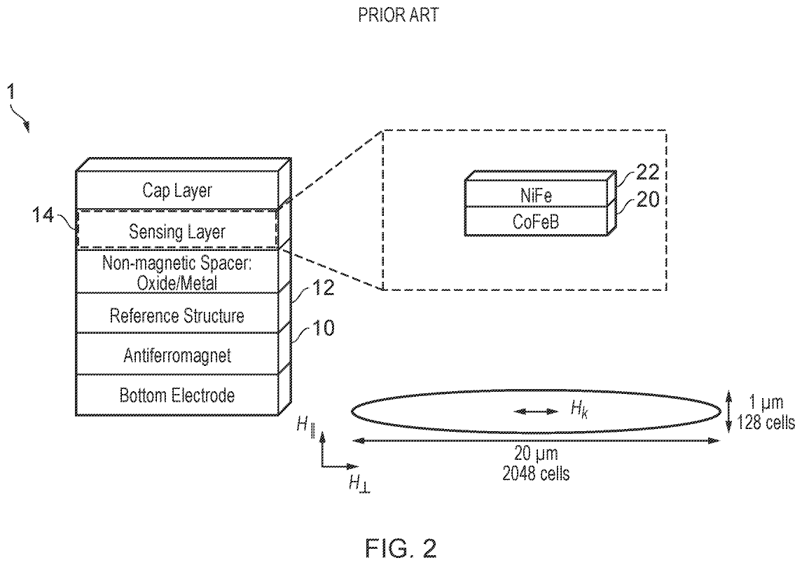

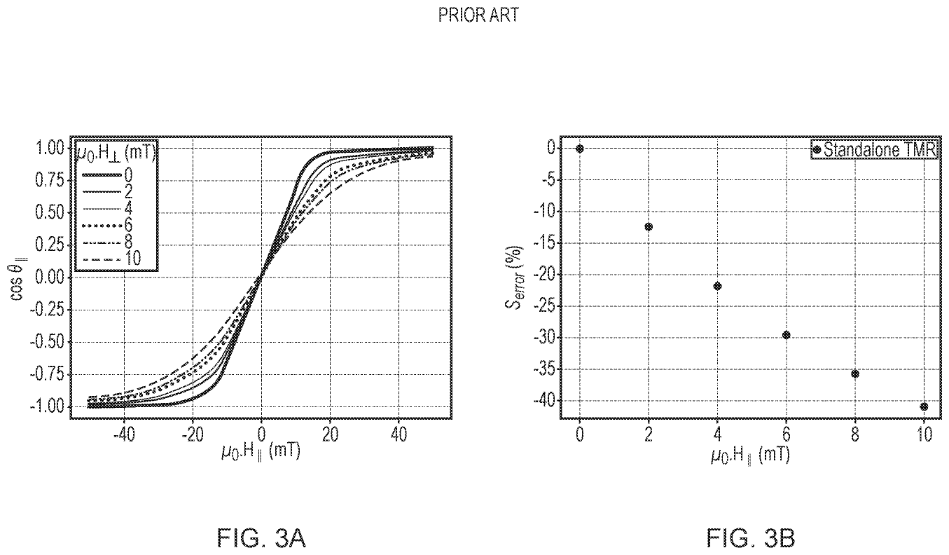

FIGS. 2 and 3A-3B illustrate how the sensitivity is affected by a cross field for sensing devices that have undergone uniaxial linearization. In this example, the sensing layer 14 of the xMR stack 1, having a high aspect ratio and a low sensitivity, comprises a first ferromagnetic layer 20, which in this case is a layer of cobalt iron boron (CoFeB), and a second ferromagnetic layer 22, which in this case is nickel iron (NiFe), to thereby provide the required shape anisotropy, Hₖ.

The sensor response, μ₀. H_{∥}, where μ₀ is the magnetic permeability and H_{∥} is the magnetic field parallel to the sensing axis, is independent of the cross field polarity, however, as shown in FIG. 3A, there is a continuous non-linear decrease in the sensitivity as the absolute cross field (μ₀. H_{⊥}) increases, where H_{⊥} is the cross magnetic field perpendicular to the sensing axis. Moreover, the sensitivity error increases as the cross-field increases. In this respect, the sensitivity error can be calculated as follows:

$${S}_{error} = \frac{{S}_{H ⊥} - {S}_{H {⊥}^{= 0}}}{{S}_{H {⊥}^{= 0}}} \times 100 \qquad [ 1 ]$$

Wherein S_{H}_{_{⊥}} is the sensor sensitivity with a non-null cross field, and S_{H}_{_{⊥}}₌₀ is the sensor sensitivity in the absence of a cross-field.

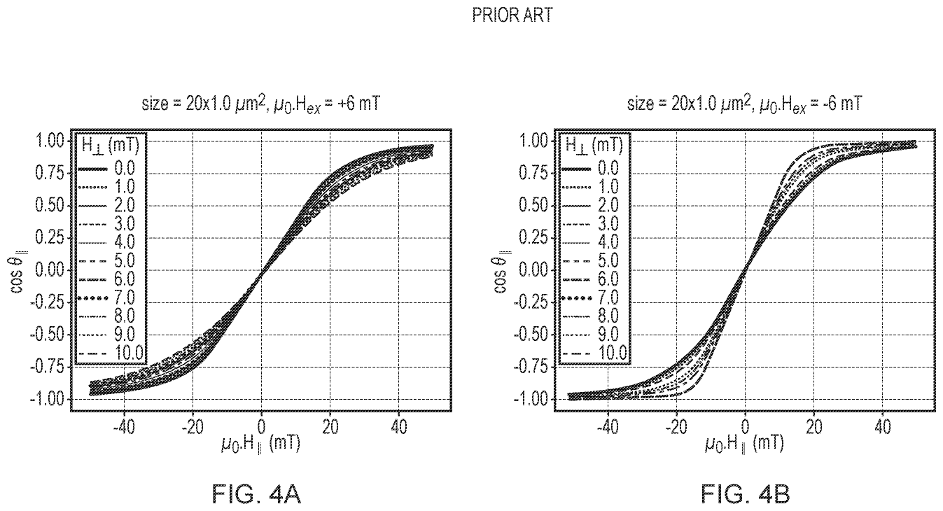

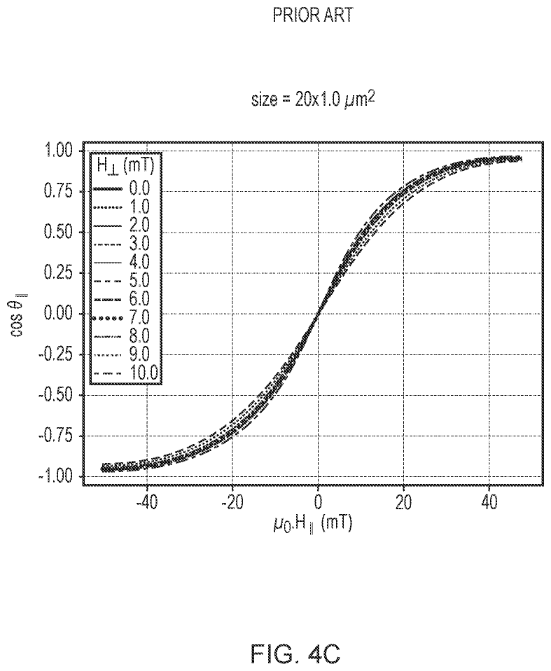

FIGS. 4A-C illustrate how the sensitivity is affected by a cross field for sensing devices that have undergone unidirectional linearization. In this example, a biasing field (H_{bias}) is applied to the sensing layers of xMR sensor elements that have an aspect ratio of 20×1.0 μm². FIG. 4A shows the effect of applying a cross field with the same polarity as the sensing layer biasing field, from which it can be seen that the sensitivity decreases with increasing cross field. FIG. 4B shows the effect of applying a cross field with the opposite polarity as the sensing layer biasing field, from which it can be seen that the sensitivity increases with increasing cross field until H_{bias}+H_{⊥}=0, after which point the sensitivity starts to decrease. As shown by FIG. 4C, if a combination of xMR sensor elements with a differential sensing layer bias field are connected in series, the impact of the cross field on the sensitivity is reduced.

However, there are number of disadvantages when implementing a differential biasing field alone to reduce the effect of any cross fields. Firstly, the use of a differential biasing field from an electromagnet does not provide a wide operating range without cross field interference, and it requires a current to be constantly applied. Similarly, the integration of permanent magnets is not compatible with applications in harsh environments and the magnets can be easily re-magnetized under a high external field. Additionally, the combination of pairs of sensors with the same properties and an antiparallel sensing layer biasing does not provide a full compensation of the cross field because the impact of the cross field on the sensitivity is not linear.

The present disclosure therefore seeks to provide an xMR magnetic field sensor that provides a wide and robust range of operation, and has a sensor arrangement that is able to deliver an improved mitigation of the cross field effect.

More specifically, the present disclosure provides a magnetoresistive sensing device that combines multiple pairs of sensors that have a differential sensing layer bias, different sensitivities and opposite reference directions (i.e., the magnetization direction of the reference structure), to thereby reduce effect of cross fields. In some cases, the differential sensing layer bias is provided by exchange bias coupling between the sensing layer and an adjacent antiferromagnet layer. However, it will of course be appreciated that the differential sensing layer bias could be provided using any suitable differential sensing layer technique, for example, applying an external biasing field with permanent magnets or an electromagnet.

The magnetoresistive sensor described herein provides a number of advantages, including being more robust to harsh environments, having a wider cross field immunity window with lower output error, being less susceptible to re-pinning and not necessarily requiring multiple dies and/or multiple film types to manufacture.

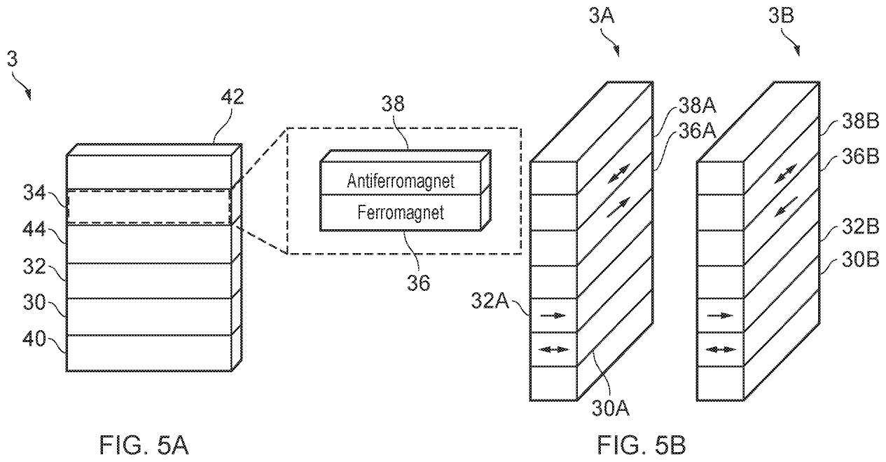

FIG. 5A illustrates an xMR stack 3 of a sensing element that may be used in accordance with the present disclosure. As before, the xMR stack 3 comprises an antiferromagnet layer 30 and a reference structure 32, which are configured to set a fixed magnetization direction that does not rotate within the operating range of the sensor. In this example, the sensing layer 34 comprises a ferromagnetic region 36 and an antiferromagnetic layer 38 to effectively provide a soft pinned sensing layer 34.

The xMR stack 3 also comprises a bottom electrode 40 for electrically connecting the xMR stack 3, and a capping layer 42 for protecting the xMR stack 3. Additionally, a non-magnetic spacer 44 is provided between the reference structure 32 and the sensing layer 34. In the case of a GMR stack, the non-magnetic spacer 44 may be formed from any suitable metal material, for example, copper. In the case of a TMR stack, the non-magnetic spacer 44 may be formed from any suitable oxide material, for example, magnesium oxide (MgO) or aluminium oxide (Al₂O₃).

FIG. 5B illustrates a pair of sensing elements 3A, 3B in accordance with the present disclosure. In this example, the magnetization directions of the reference structures 32A, 32B are fixed in the same direction, whilst the ferromagnetic layers 36A, 36B have antiparallel magnetisation directions.

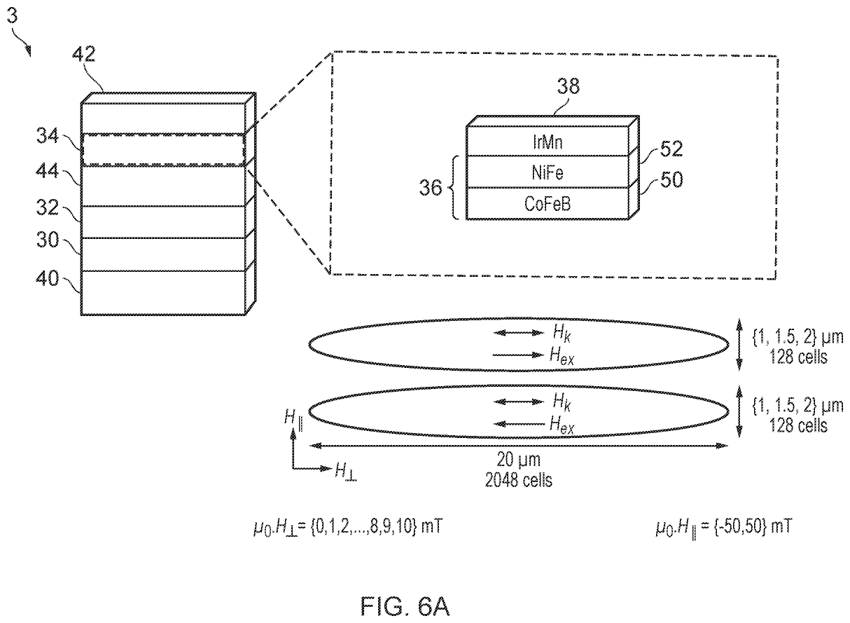

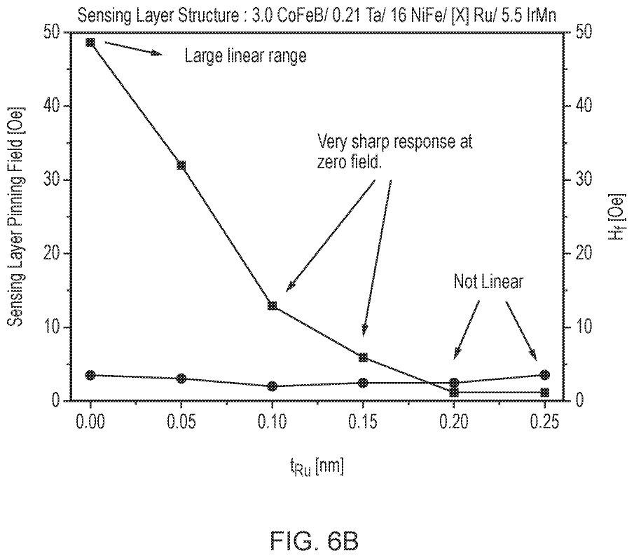

FIG. 6A further illustrates the xMR stack 3 shown in FIGS. 5A-5B. As before, the ferromagnetic region 36 of the sensing layer 34 comprises a first ferromagnetic layer 50, and a second ferromagnetic layer 52. The first and second ferromagnetic layers 50, 52 may be formed from any suitable ferromagnetic materials, such as CoFeB, NiFe or cobalt iron (CoFe). The antiferromagnetic layer 38 may comprise any suitable antiferromagnetic material, such as iridium manganese (IrMn) or platinum manganese (PtMn).

The two ferromagnetic layers 50, 52 are coupled through an exchange bias with the antiferromagnetic layer 38, and thereby softly pins the magnetisation direction of the ferromagnetic region 36 in a particular direction. By providing pair of sensing elements with antiparallel magnetisation directions (as shown in FIG. 5B), a differential sensing layer bias is provided. The amplitude of the exchange bias can be tuned by the ferromagnetic and antiferromagnetic material. For example, as shown in FIG. 6B (R. Ferreira et al., Large Area and Low Aspect Ratio Linear Magnetic Tunnel Junction With a Soft-Pinned Sensing Layer, IEEE Transactions on Magnetics, vol. 48, n. 11, 2012), the amplitude of the pinning field (i.e., the biasing field) can be increased or decreased by varying the thickness of a layer of non-magnetic material, for example, ruthenium, between the ferromagnetic region 36 and the antiferromagnetic layer 38.

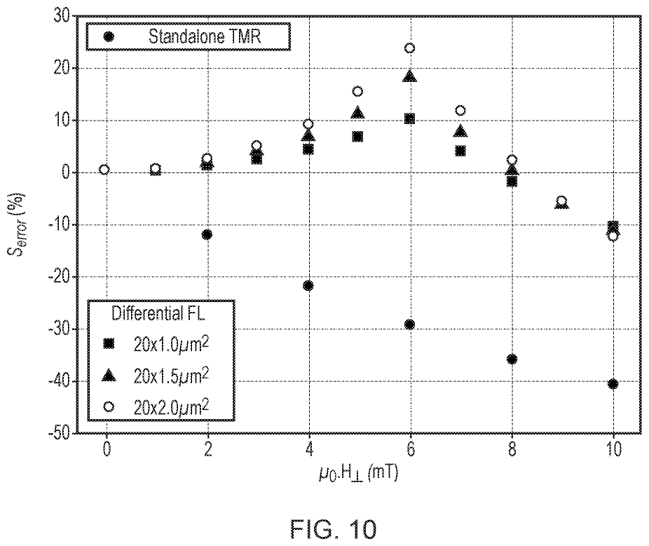

The exchange bias field, Hₑₓ, is unidirectional which leads to a sensor output dependent on cross field polarity when one or more pairs of sensing elements are implemented in magnetoresistive sensing device. The sensitivity of the sensing device will increase when ┌Hₑₓ+H_{⊥}┐ decreases, and so the cross field immunity window is limited by Hₑₓ. The sensing device will still operate above that value but with a higher sensitivity variation, since the sensitivity of both sensing elements decreases (as will be described below with reference to FIG. 10).

Whilst the above describes using pairs of sensing elements with ferromagnetic regions 36 that are softly pinned in antiparallel directions, it will of course be appreciated that the differential biasing may be provided through other methods described herein (e.g., by applying an external biasing field using permanent magnets), in which case the antiferromagnetic layer 38 may be omitted from the xMR stack 32.

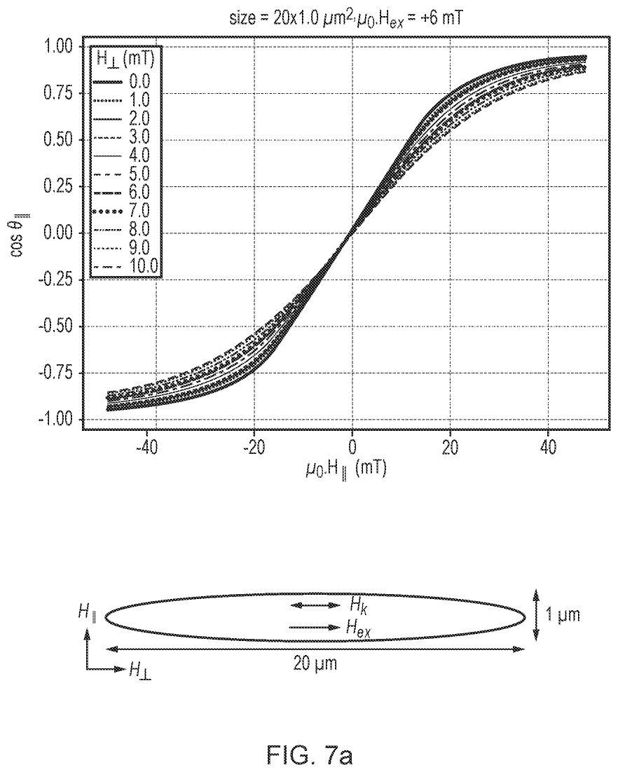

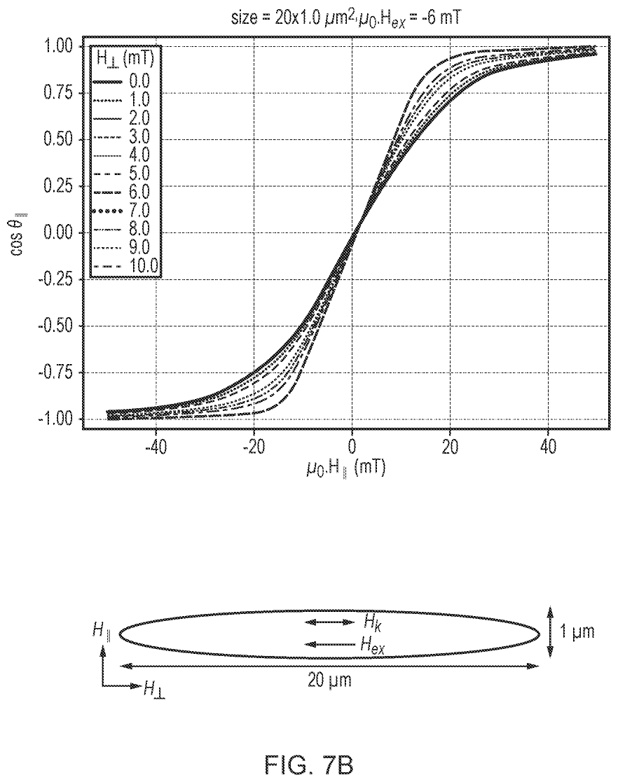

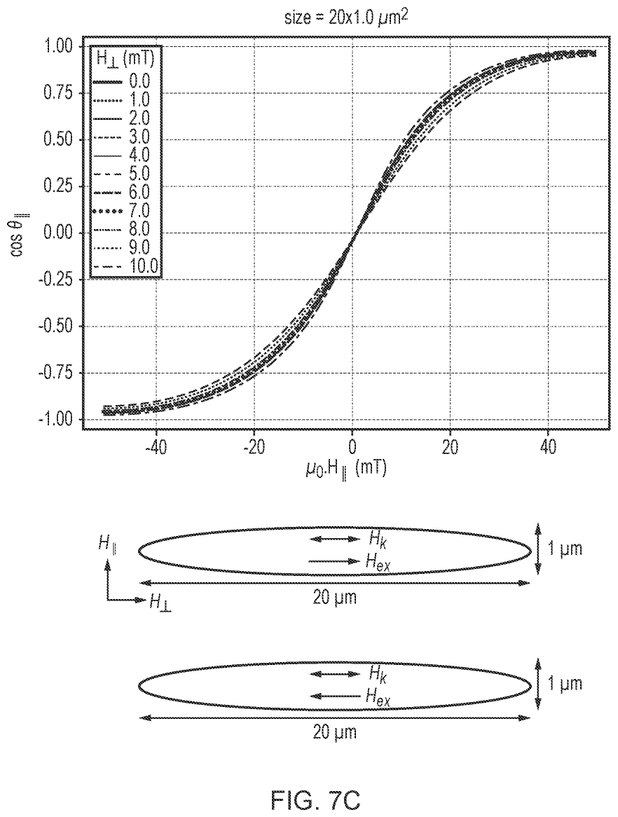

FIGS. 7-9 illustrate the impact of a cross field on xMR sensing devices having sensing elements with differential soft pinned sensing layers, and the change in that impact if the sensitivities of the sensing elements are varied by changing the aspect ratio. In this respect, it will be appreciated that the xMR sensing devices may have any number of sensing elements connected in series or in parallel.

FIGS. 7A-C illustrate the impact of a cross field on xMR sensing devices having sensing elements with a first sensitivity provided by an aspect ratio of 20×1.0 μm². FIG. 7A shows the sensitivity when the cross field and sensing layer exchange field have the same polarity. FIG. 7B shows the sensitivity when the cross field and sensing layer exchange field have the opposite polarities. FIG. 7C shows the impact when an even combination of xMR sensing elements with antiparallel sensing layer exchange fields are connected in series, to thereby provide pairs of xMR sensing elements with the differential soft pinned sensing layers. As can be seen from FIG. 7C, the sensitivity variation is significantly reduced by implementing a different soft pinned sensing layer arrangement.

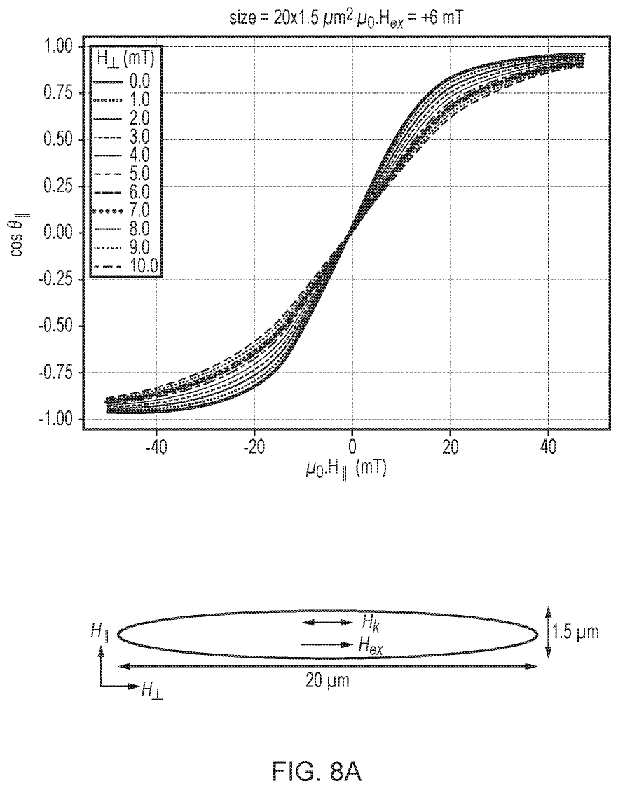

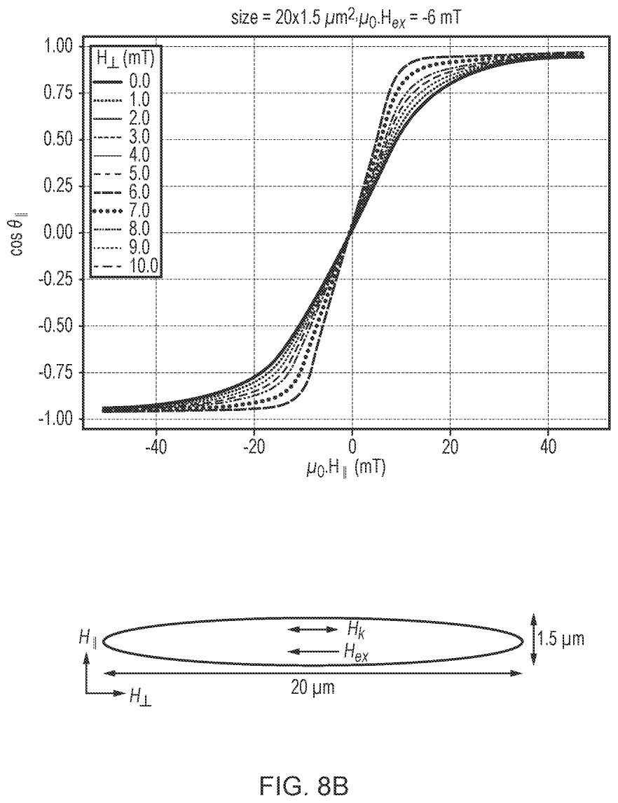

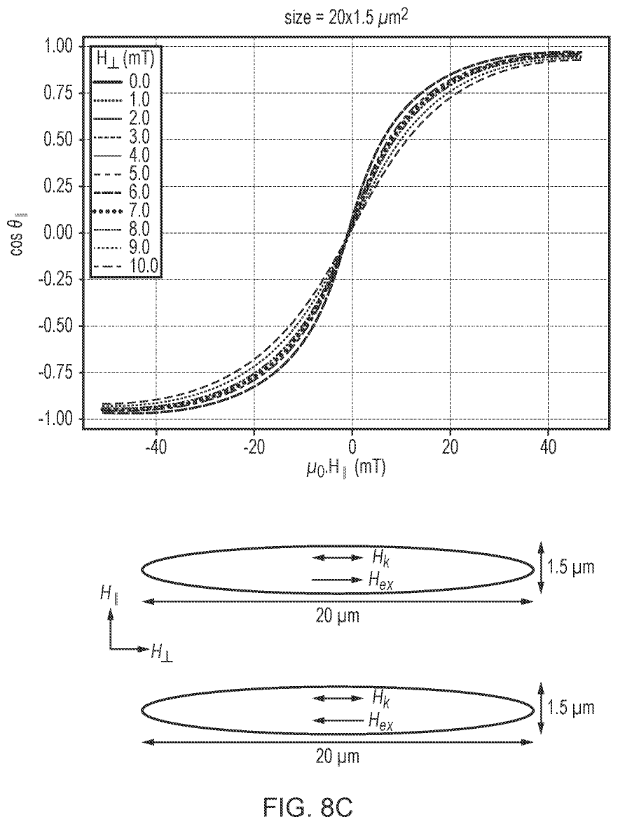

FIGS. 8A-C illustrate the impact of a cross field on xMR sensing devices having sensing elements with a second sensitivity provided by an aspect ratio of 20×1.5 μm². FIG. 8A shows the sensitivity when the cross field and sensing layer exchange field have the same polarity. FIG. 8B shows the sensitivity when the cross field and sensing layer exchange field have the opposite polarities. FIG. 8C shows the impact when an even combination of xMR sensing elements with antiparallel sensing layer exchange fields are connected in series, to thereby provide pairs of xMR sensing elements with the differential soft pinned sensing layers. As can be seen from FIG. 8C, the sensitivity variation is again significantly reduced by implementing a different soft pinned sensing layer arrangement, and the overall sensitivity is increased by using a smaller aspect ratio.

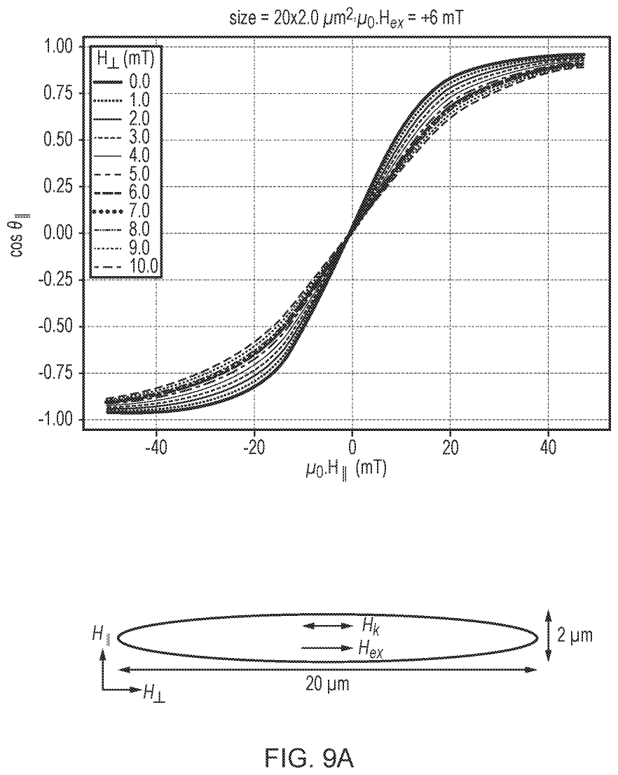

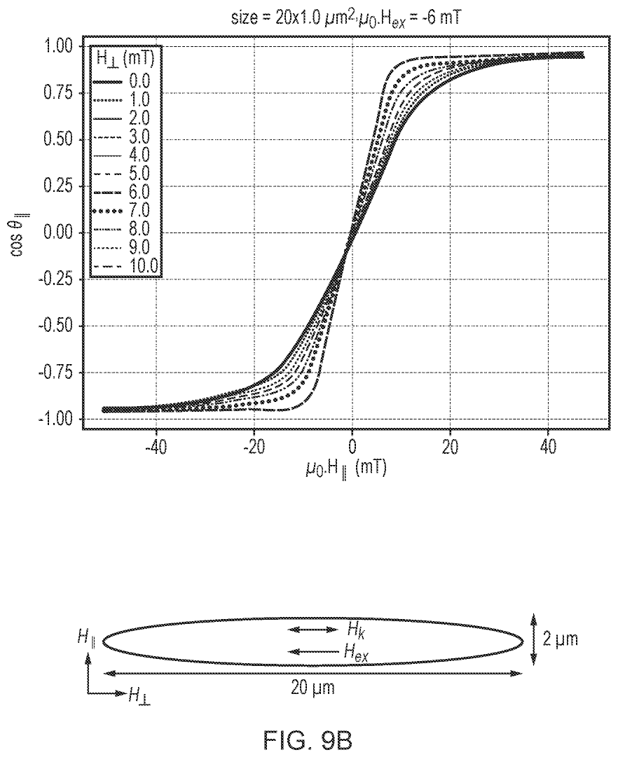

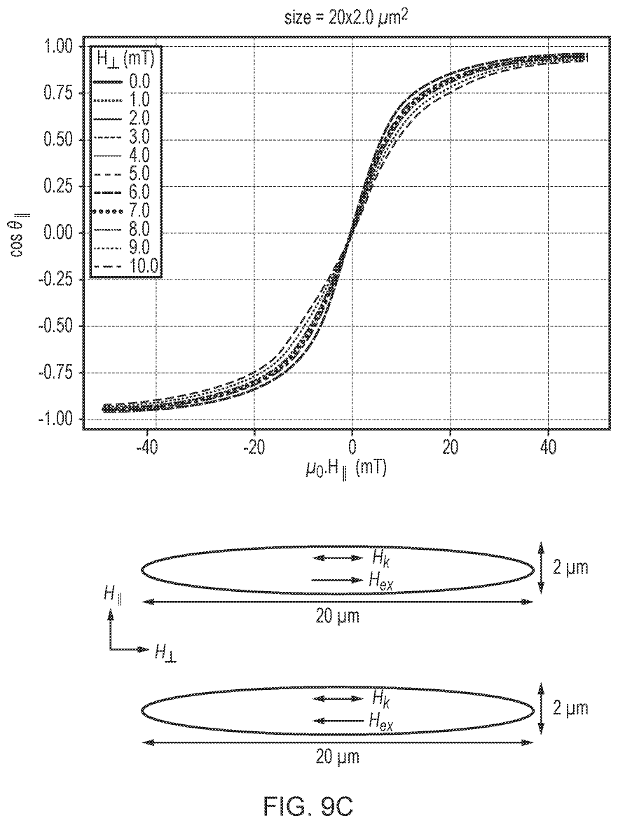

FIGS. 9A-C illustrate the impact of a cross field on xMR sensing devices having sensing elements with a third sensitivity provided by an aspect ratio of 20×2.0 μm². FIG. 9A shows the sensitivity when the cross field and sensing layer exchange field have the same polarity. FIG. 9B shows the sensitivity when the cross field and sensing layer exchange field have the opposite polarities. FIG. 9C shows the impact when an even combination of xMR sensing elements with antiparallel sensing layer exchange fields are connected in series, to thereby provide pairs of xMR sensing elements with the differential soft pinned sensing layers. As can be seen from FIG. 9C, the sensitivity variation is again significantly reduced by implementing a different soft pinned sensing layer arrangement, and the overall sensitivity is increased further by the reduced aspect ratio.

FIG. 10 shows the sensitivity error for each of sensor outputs shown in FIGS. 7C, 8C and 9C, compared to that of the typical xMR sensor shown in FIGS. 3A-B. From FIG. 10, it is clear that the use of xMR sensing elements with antiparallel sensing layer exchange fields reduces the sensitivity error when a cross field is present. Furthermore, whilst the arrangements comprising sensor elements with higher aspect ratios provides a lower sensitivity, the sensitivity error for such arrangements is lower.

Therefore, the present disclosure proposes a combination of differential sensing layer sensing elements with different sensitivities to enhance the cross field immunity. To achieve this, a combination of differential sensing layer sensing elements with different pinning directions (i.e., reference directions) is also implemented, as a combination of differential sensing layer sensing elements with different sensitivities and the same reference direction will lead to an arrangement where all of the sensing elements have a relatively low sensitivity. In this respect, as illustrated by FIGS. 7C, 8C, 9C and 10, all of the sensing elements will still have some cross-field sensitivity, wherein the sensing elements with a higher sensitivity have a higher sensitivity error, which will result in a reduced sensitivity across all of the sensing elements. By combining sensing elements of different sensitivities with different reference directions, the sensitivity to cross fields is effectively reversed in some of the sensing elements, thereby cancelling out the impact of the cross field in the other sensing elements.

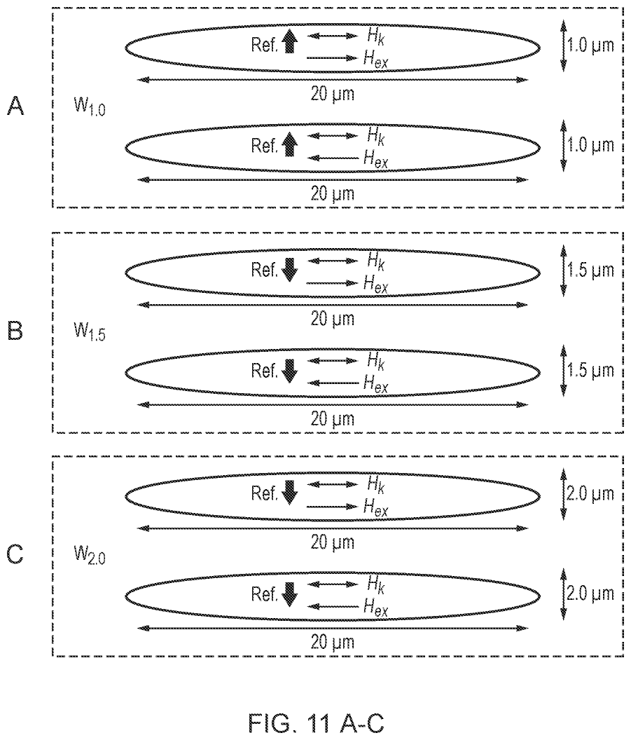

An example of an optimised combination of differential sensing layer sensing elements will now be described, with reference to FIGS. 11A-C and 12A-B.

In this example, differential sensing layer sensing elements with three different sensitivities are combined. In this example, three different aspect ratios are used to provide the three different sensitivities, wherein the sensing elements with the lowest sensitivity (i.e., the highest aspect ratio) and the highest sensitivity (i.e., the lowest aspect ratios) have anti parallel reference structures. The differential sensing layer sensing elements with the highest aspect ratio (e.g., 20×1.0 μm²) define the sensing direction by virtue of the magnetization direction of their reference structures, as shown by FIG. 11A. The differential sensing layer sensing elements with the lower aspect ratios (e.g., 20×1.5 μm² and 20×2.0 μm²) have the opposite sensing direction (i.e., antiparallel pinning direction) in order to attenuate the non-linear increase of the sensitivity error, as shown by FIGS. 11B-C.

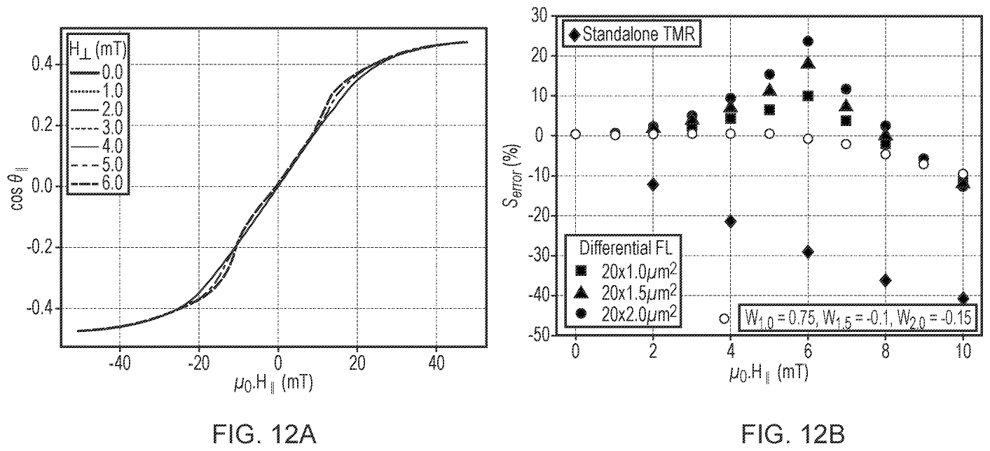

As shown in FIG. 12A, the combination of a differential soft pinned sensor layer with different aspect ratios and opposite reference directions leads to an enhanced immunity to cross fields. Each array of differential sensing layer sensing elements will represent a percentage W_{width} (W_{1.0}, W_{1.5} and W_{2.0}) of the final output generated by a full array of sensing elements in series to achieve the optimal immunity to cross-fields, which will depend on the combination of aspect ratios being implemented. In FIG. 12A, the optimal ratio of outputs is 75% for the sensing elements having an aspect ratio of 20×1.0 μm², 10% for the sensing elements having an aspect ratio of 20×1.5 μm², and 15% for the sensing elements having an aspect ratio of 20×2.0 μm². In this respect, the sensing elements with a higher aspect ratio and lower sensitivity error provide a larger contribution to the output signal. As shown in FIG. 12B, the sensitivity error of this combination of differential soft pinned sensing elements provides a negligible or near-negligible sensitivity error in the presence of a cross field that is equal or below the strength of the biasing field, with a relatively small error in the sensitivity only being seen at higher strength cross fields (e.g., above 6 mT).

Whilst the above example uses different aspect ratios to provide sensing elements of varying sensitivity, it will be appreciated that the sensing elements may be provided with different respective sensitivities in a number of different ways. For example, the sensitivities may be varied by using sensing elements with different xMR stack arrangements, for example, comprising different sensing layer compositions, or by applying different biasing fields to the sensing layer to provide different amounts of soft pinning. As another example, the sensitivities may be varied by applying an additional external field to one or more of the sensing elements (e.g., through a field produced by an electromagnet or a permanent magnet) to thereby vary the biasing field.

For example, in the arrangement shown in FIG. 11, the sensors with the lower aspect ratio could be replaced by sensing elements with a higher aspect ratio, but comprising an xMR stack with a lower biasing field in the sensing layer to provide increased sensitivity, or by reducing the biasing field through a field produced by an electromagnet or a permanent magnet in the opposite direction, and still obtain the same enhanced immunity. This array of sensing elements can be implemented as a standalone magnetic sensor array or in a Wheatstone bridge configuration, as will be described below, for an enhanced performance in terms of background signal reduction and thermal response. A similar strategy can be employed in a range of cross fields higher than the exchange bias field, if the output of both sensing elements in each differential sensor pair is acquired, a post process circuit can determine which sensing element is providing the correct value.

Additionally, whilst the above examples provide aspect ratios of 20×1 μm², 20×1.5 μm² and 20×2.0 μm², it will of course be appreciated that these are exemplary and any suitable aspect ratio may be used.

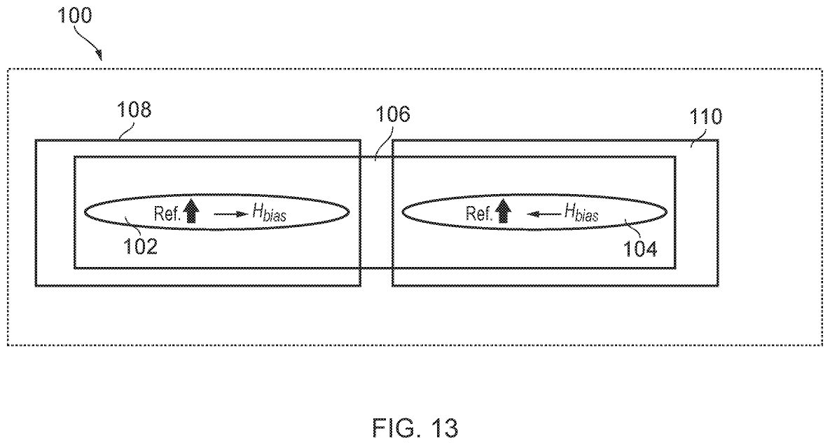

FIG. 13 shows an example 100 of a pair of tunnel magnetoresistive (TMR) sensing elements with differential sensing layer bias. In this example, a first TMR sensing element 102 and a second TMR sensing element 104 are disposed on a first electrical contact 106, each having further electrical contacts 108, 110 disposed over the top for electrically connecting the sensing elements 102, 104 in a circuit. As can be seen from FIG. 13, both sensing elements 102, 104 have reference structures pinned in the same direction, and opposing biasing fields, H_{bias}.

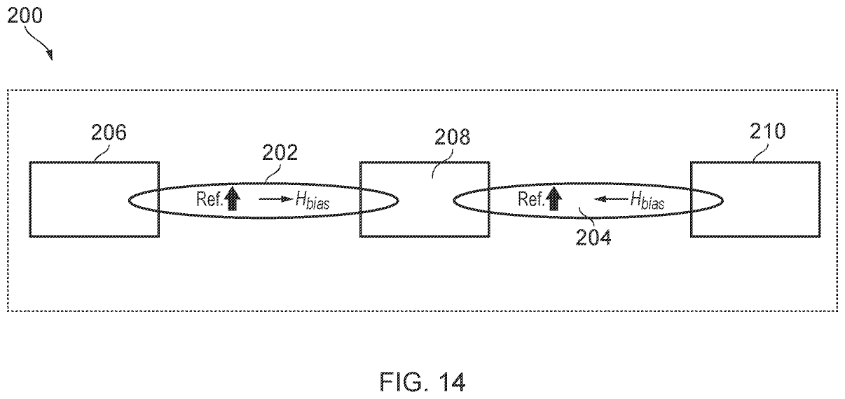

FIG. 14 shows an example 200 of a pair of giant magnetoresistive (GMR) sensing elements with differential sensing layer bias. In this example, a first GMR sensing element 202 and a second GMR sensing element 204 are disposed between and in contact to electrical contacts 206, 208 and 210, to thereby connect the sensing elements 202, 204 in a circuit. Again, both sensing elements 202, 204 have reference structures pinned in the same direction, and opposing biasing fields, H_{bias}.

In the examples of FIGS. 13 and 14, the biasing field is induced through exchange bias by way of sensing layers that are softly pinned in opposing directions. However, it will be appreciated that the biasing field may also be induced externally by permanent magnets or an electromagnet. That is to say, the differential biasing of the sensing layers may be provided through soft pinning of the sensing layer, as described with reference to FIGS. 5A, 5B and 6A, or by a biasing field generated by permanent magnets or an electromagnet.

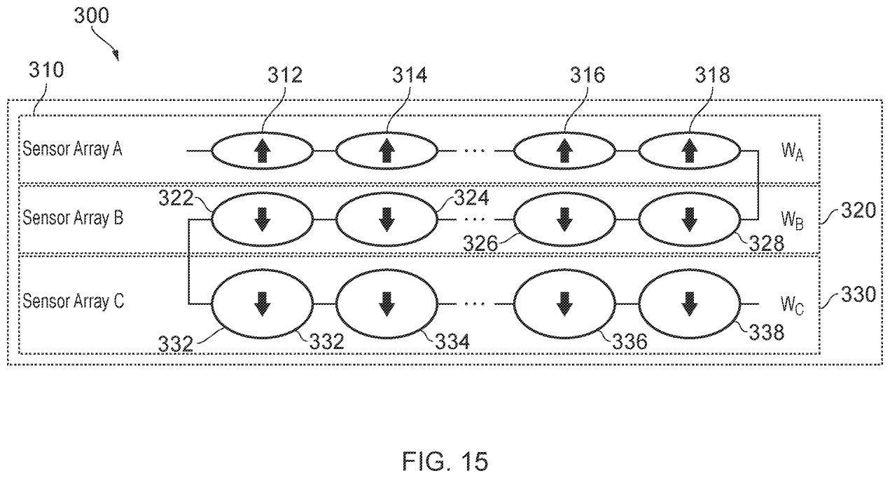

FIG. 15 illustrates an example magnetic sensor 300 comprising multiple arrays of sensing elements, wherein the arrays of sensing elements have differential sensing layer bias, different sensitivities and varying reference magnetization direction. It will be appreciated that the pairs of sensing elements within each array maybe TMR or GMR based sensing elements, as illustrated by FIGS. 13 and 14.

The magnetic sensor 300 comprises a first sensor array 310, a second sensor array 320 and a third sensor array 330, each comprising sensing elements connected in series, however, it will be appreciated that the sensing elements of each array may also be connected in parallel. The first sensor array 310 comprises a plurality of sensing elements having a first sensitivity, shown here as a first pair of sensing elements 312, a second pair of sensing elements 314, a third pair of sensing elements 316 and a fourth pair of sensing elements 318. The second sensor array 320 comprises plurality of sensing elements having a second sensitivity, shown here as a first pair of sensing elements 322, a second pair of sensing elements 324, a third pair of sensing elements 326 and a fourth pair of sensing elements 328. The third sensor array 330 comprises plurality of sensing elements having a third sensitivity, shown here as a first pair of sensor elements 332, a second pair of sensing elements 334, a third pair of sensing elements 336 and a fourth pair of sensor elements 338. It will be appreciated that each pair of sensing elements 312-338 may have a similar configuration to that shown in FIGS. 13 and 14 (i.e., 100 and 200). In this example, the sensitivities of the sensing elements in each sensor array 310, 320 and 330 is defined by the aspect ratio therein, however, it will of course be appreciated that the different sensitivities may be provided by some other means, as described above. The arrows within each pair of sensing elements represents the pinning direction of the reference structure (i.e., the reference magnetization direction), and the illustrated size of each pair of sensing elements represents the relative difference between the sensitivities and/or the amplitude of the bias fields. In this respect, a smaller sensing element illustrates a lower sensitivity (i.e., higher aspect ratio) and/or higher biasing field and a larger sensing element illustrates a higher sensitivity (i.e., lower aspect ratio) and/or lower biasing field. It can therefore be seen that the first sensitivity of the first sensor array 310 is lower than the second sensitivity of the second sensor array 320, which in turn is lower than the third sensitivity of the third sensor array 330.

Whilst four pairs of sensing elements are shown in each sensory array, it will be appreciated that any number of sensing elements may be included in each sensor array depending on the percentage weighting W of each sensitivity, as will be described further below.

As the first sensor array 310 comprises sensing elements with the lowest sensitivity (i.e., highest aspect ratio), it defines the sensing direction, as determined by the reference magnetization direction. The first sensor array 310 will comprise N_{A} sensing elements that will represent a first percentage WA of the magnetic sensor output. The second and third sensor arrays 320, 330 attenuate the cross field effect with an antiparallel pinning direction and a higher sensitivity (i.e., lower aspect ratio). The second sensor array 320 will comprise N_{B} sensing elements that will represent a percentage W_{B} of the magnetic sensor output, and the third sensor array 330 will comprise N_{C} sensing elements that will represent a first percentage W_{C} of the magnetic sensor output. As the sensing elements of the second and third sensor arrays 320, 330 have a higher sensitivity, they will be more susceptible to cross fields and so these sensor arrays will typically represent a lower percentage of the magnetic sensor output.

Whilst three sensor arrays are shown in FIG. 15, it will be appreciated that a magnetic sensor in accordance with the present disclosure may be implemented with two or more sensor arrays, comprising at least a first sensor array defining the sensing direction and at least one further sensor array with antiparallel pinning direction to improve the mitigation of the cross field effect. The magnetic sensor is thus formed by the combination of the sensor arrays i (i being the number of sensor arrays) with a weight Wᵢ (ΣWᵢ=1).

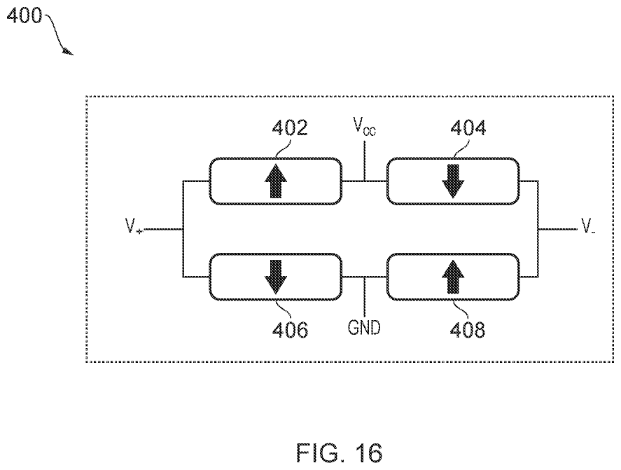

The magnetic sensor 300 can operate in a single ended mode (i.e., as a single magnetic sensor) or it can be arranged in a Wheatstone bridge arrangement comprising multiple magnetic sensors, as shown in FIG. 16. FIG. 16 shows a magnetic sensing device 400 comprising a plurality of magnetic sensors 402, 404, 406 and 408 connected in a Wheatstone bridge configuration. Each of the magnetic sensors 402, 404, 406 and 408 comprises two or more sensor arrays as described herein, for example, each of magnetic sensors 402, 404, 406 and 408 may have the configuration of the magnetic sensor 300 shown in FIG. 15.

When arranging the magnetic sensing device 400 in a Wheatstone bridge configuration, it will be important for each sensor array within the magnetic sensor 402, 404, 406 and 408 to deliver the same resistance level. In this example, the optimum weighting (i.e., percentage W) for each aspect ratio being used can be obtained by numerically combining the simulated response of each type of sensing element, to thereby determine a combination of those sensing elements that will provide the required resistance level. Therefore, in the case where the sensitivity of each array is varied through the use of sensing elements with different aspect ratios, the weights W may be compensated in terms of the resistance level of each aspect ratio. For example, referring back to the case of a TMR based magnetic sensor (e.g., magnetic sensor 300 as shown in FIG. 15 comprising pairs of TMR sensing elements as shown in FIG. 13) with three arrays of sensing elements having areas of 20×1.0 μm², 20×1.5 μm² and 20×2.0 μm² with the same weightings described with reference to FIG. 12A, the total number of sensing elements per array can be calculated as shown in Table 1 below.

TABLE 1

| Sensor | Size | | | Weight | |
|---|---|---|---|---|---|
| Array | (μm²) | Resistance | N | (%) | Total |
| 1 | 20 × 1.0 | ${R}_{1.} = N \frac{R \times A}{{A}_{1.}} = {N}_{1.} R$ | 4 | 75 | 30 |
| 2 | 20 × 1.5 | ${R}_{1.5} = \frac{2}{3} {N}_{1.5} R$ | 6 | 10 | 6 |
| 3 | 20 × 2.0 | ${R}_{2.0} = \frac{1}{2} {N}_{2.0} R$ | 8 | 15 | 12 |

In Table 1, R×A is the resistance times area product of the TMR film, A_{1.0,1.5,2.0} is the area of a sensing element of a given size in the array, N_{1.0, 1.5, 2.0} is the number of sensing elements of a given size in the array, and R_{1.0, 1.5, 2.0} is the total resistance of combinations the sensing elements of a given size in the array.

As such, in the case of the magnetic sensor 300 shown in FIG. 15, the first sensor array 310 would comprise 15 pairs of sensing elements (30 total), the second sensor array 320 would comprise 3 pairs of sensing elements (6 total) and the third sensor array 330 would comprise 6 pairs of sensing elements (12 total) to ensure the same resistance level and the optimum weighting is delivered across each sensor array.

As another example, referring back to the case of a GMR based magnetic sensor (e.g., magnetic sensor 300 as shown in FIG. 15 comprising pairs of GMR sensing elements as shown in FIG. 14) with three arrays of sensing elements having areas of 20×1.0 μm², 20×1.5 μm² and 20×2.0 μm² with the same weightings described with reference to FIG. 12A, the total number of sensing elements per array can be calculated as shown in Table 2 below.

TABLE 2

| Sensor | Size | | | Weight | |
|---|---|---|---|---|---|
| Array | (μm²) | Resistance | N | (%) | Total |
| 1 | 20 × 1.0 | ${R}_{1.0} = N \frac{{R}_{sheet} l}{w} = {N}_{1.0} R$ | 4 | 75 | 30 |
| 2 | 20 × 1.5 | ${R}_{1.5} = \frac{2}{3} {N}_{1.5} R$ | 6 | 10 | 6 |
| 3 | 20 × 2.0 | ${R}_{2.0} = \frac{1}{2} {N}_{2.0} R$ | 8 | 15 | 12 |

In Table 2, Rₛₕₑₑₜ is the sheet resistance of the GMR film, I is the length of a sensing element in the array, w is the width of a sensing element in the area, N_{1.0, 1.5, 2.0} is the number of sensing elements of a given size in the array, and R_{1.0, 1.5, 2.0} is the total resistance of combinations the sensing elements of a given size in the array.

It will of course be appreciated that the number of sensing elements provided in Tables 1 and 2 is exemplary and any number of sensing elements according to the weighting may be used. For example, the number of elements may be multiples of the above totals (i.e., {5, 1, 2}; {60, 12, 24}; etc.).

In some applications, it may be required to monitor an external magnetic field in two or more directions. In such cases, a magnetic sensing device 500 comprising two Wheatstone bridge arrangements 510, 520 may be provided in order to sense and measure an external magnetic field in both the x- and y-directions. The first Wheatstone bridge 510 again comprises four magnetic sensors 512, 514, 516 and 518, wherein the sensing direction (denoted by the arrows), as defined by the first sensor array within each sensor, is pinned in the y-direction. The second Wheatstone bridge 520 also comprises four magnetic sensors 522, 524, 526 and 528, however, in this case the sensing direction (denoted by the arrows), as defined by the first sensor array within each sensor, is pinned in the x-direction. It will of course be appreciated that a third Wheatstone bridge may also be implemented to monitor the magnetic field in the z-direction. It will also be appreciated that each of the magnetic sensors of each Wheatstone bridge may be implemented as the magnetic sensor 300 described with reference to FIG. 15. It will also be appreciated that when connecting the magnetic sensors in a Wheatstone bridge, each sensor of the bridge may comprise a different combination of sensing elements. In this respect, the individual magnetic sensors may not fully attenuate cross fields, but when combined in a half or full bridge, provide the required cross-field attenuation. As one example, two magnetic sensors may be connected in a first half-bridge that under-compensate for cross-fields (e.g., wherein each magnetic sensor comprises a first array comprising 4 sensing elements, a second array comprising 6 sensor elements, and a third array comprising 7 sensor elements), and two further magnetic sensors may be connected in a second half bridge that over-compensate for cross-fields (e.g., wherein each magnetic sensor comprises a first array comprising 4 sensing elements, a second array comprising 6 sensor elements, and a third array comprising 9 sensor elements), such that when connected in a full bridge, the required compensation is provided.

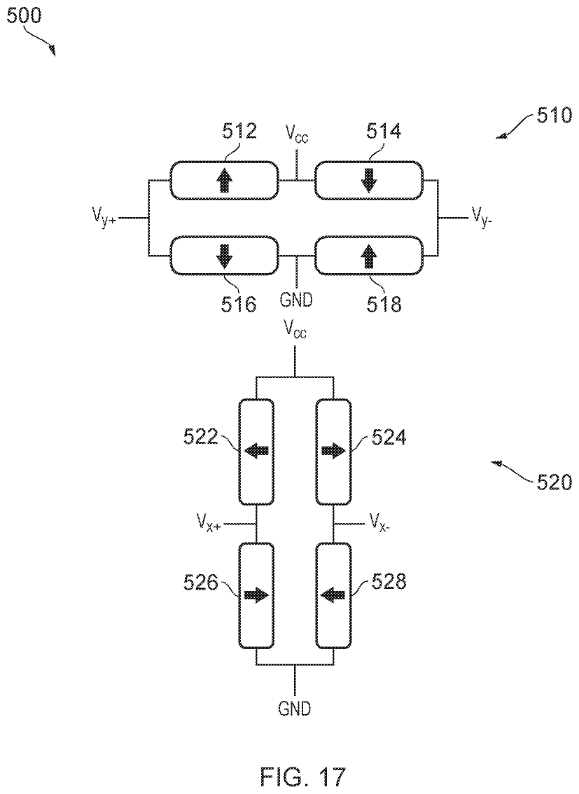

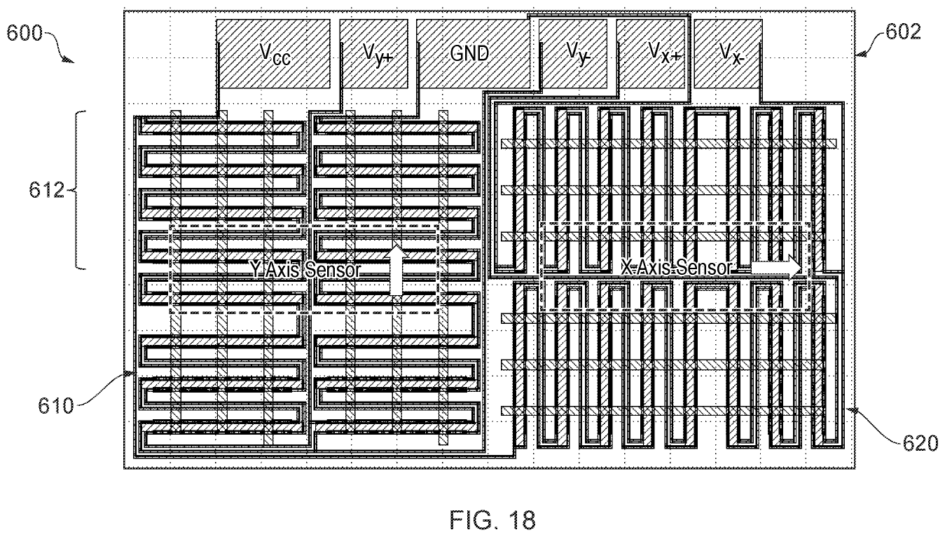

FIG. 18 illustrates an example layout of a magnetic sensing device 600 comprising a first magnetic sensor 610 configured to measure the magnetic field in the y-direction and a second magnetic sensor 620 configured to measure the magnetic field in the x-direction. In this respect, the first and second magnetic sensors 610, 620 may be implemented as the first and second Wheatstone bridge arrangements 510, 520 shown in FIG. 17, each magnetic sensor 612 comprises two or more sensor arrays such as that shown in FIG. 15. The first and second magnetic sensors 610, 620 may be arranged on the same or separate sensor dies, which may then be arranged on an application specific integrated circuit (ASIC) die 602 that is formed onto a laminate substrate such as a printed circuit board (PCB) substrate, ceramic substrate, or any suitable type of substrate.

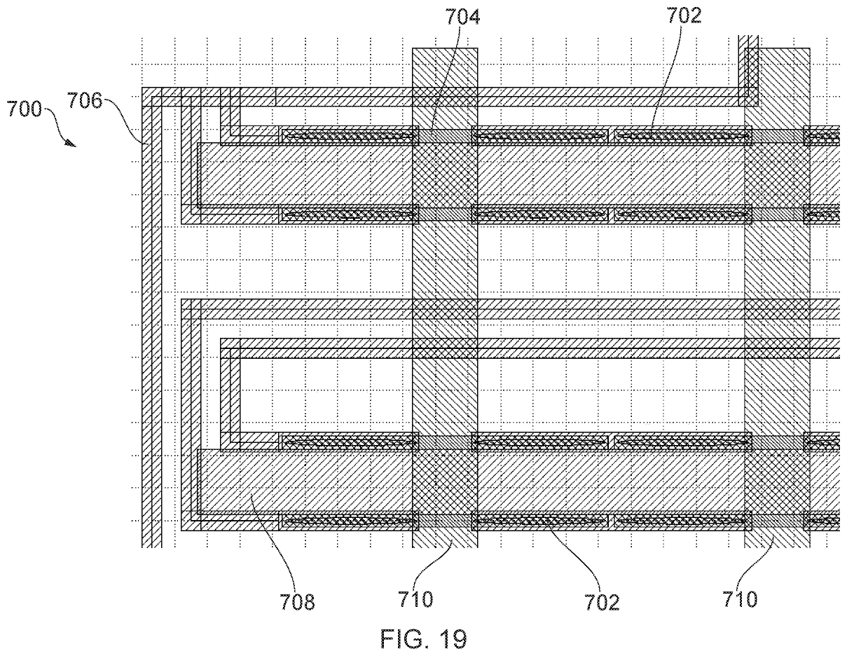

FIG. 19 illustrates an example layout of a magnetic sensing device 700 in accordance with the present disclosure that uses pairs of TMR sensing elements 702 that are electrically connected via a bottom electrode 704, similar to that shown in FIG. 13. A contact 706 is also provided for connecting the TMR sensing elements 702 to the circuitry components. Each array is provided with a flux concentrator 708 for setting the magnetisation direction of the reference layer. Each pair of TMR sensing elements are also provided with a further flux concentrator 710 for setting the magnetisation direction of the sensing layers, which in turn sets the exchange bias field. It will be appreciated that the further flux concentrator 710 will be removed after the pinning process has been performed. An example of how this may be done is provided in U.S. Pat. No. 10,151,806.

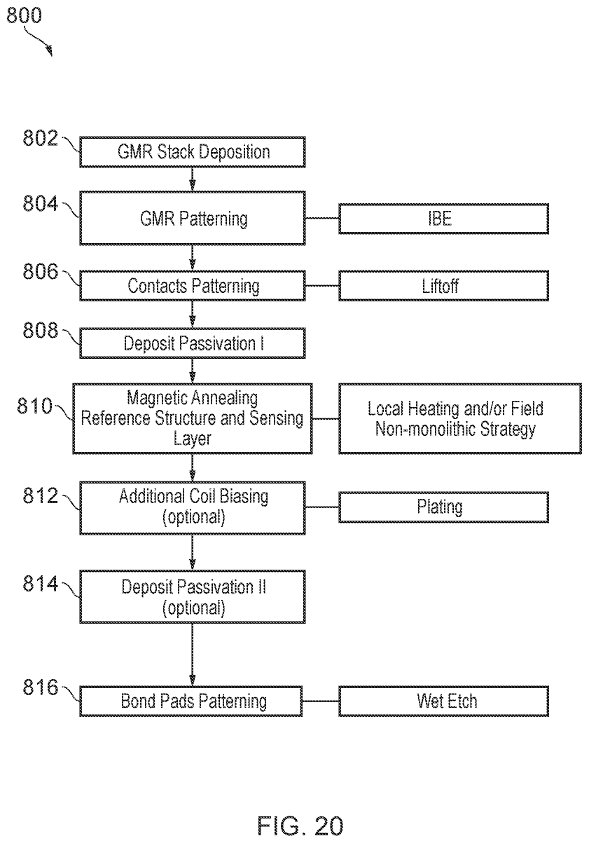

FIG. 20 is a flow diagram illustrating a method 800 of fabricating the sensor elements of a GMR-based magnetic sensor in accordance with the present disclosure. In a first step 802, a blanket GMR stack (e.g., the xMR stack 3 shown in FIG. 5A) is deposited onto a substrate. For example, the substrate may comprise an application specific integrated circuit (ASIC) die that is formed onto a laminate substrate such as a printed circuit board (PCB) substrate, ceramic substrate, or any suitable type of substrate.

At step 804, the blanket GMR stack will be patterned into two or more arrays of sensing elements, for example, using ion beam etching techniques, with each array being patterned such that the sensing elements within a given array have a particular aspect ratio. The arrays of sensing elements will also be patterned such that an even number of sensing elements is provided. In the next step 806, the metal contacts for connecting the sensing elements in series are provided. This may be done by applying a lift-off resist coating, depositing the metal material, and then performing the lift-off to create the metal contacts.

At step 808, a first layer of passivation material may be deposited for protecting the GMR sensing elements. A process of magnetic annealing 810 is then performed in order set the magnetisation directions of the reference layer and the sensing layer of the GMR sensing elements. This may be done through local heating and/or magnetic field, or using a non-wafer level solution . It will of course be appreciated that the magnetisation direction of the reference layer (i.e., the reference direction) may be set using a number of different methods.

At step 812, additional coil biasing may be performed, for example, by plating the surface with a metal material. In this respect, an electromagnet may be fabricated to increase the biasing field in order to increase the cross-field range (i.e., the amount of cross-field that can be attenuated), or alternatively, the electromagnet may be used to generate the biasing field to thereby provide the differential biasing of the sensing layer. Similarly, a further layer of passivation material may also be deposited at 814.

Finally, at step 816, bond pads are patterned into the sensing device, for example, using a wet etch, for electrically connecting the GMR sensing device.

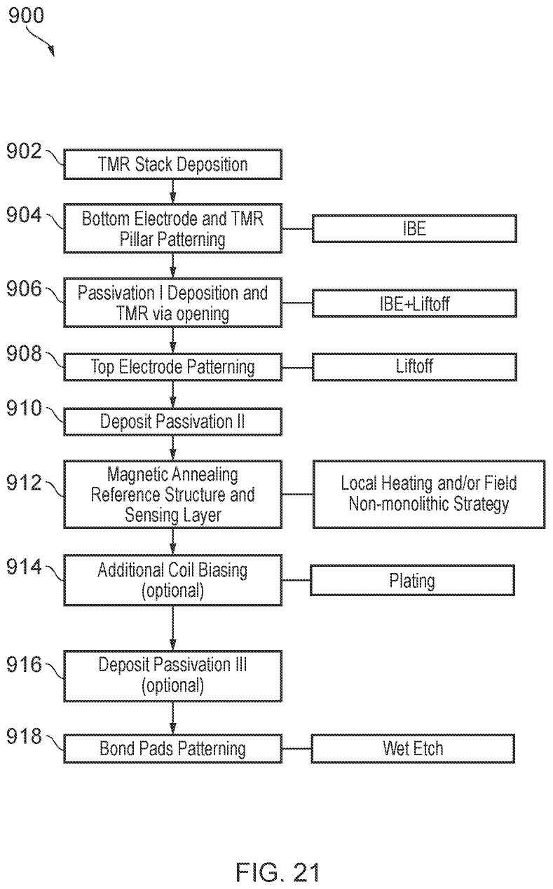

FIG. 21 is a flow diagram illustrating a method 900 of fabricating the sensor elements of a TMR-based magnetic sensor in accordance with the present disclosure. In a first step 902, a blanket TMR stack (e.g., the xMR stack 3 shown in FIG. 5A) is deposited onto a substrate. For example, the substrate may comprise an application specific integrated circuit (ASIC) die that is formed onto a laminate substrate such as a printed circuit board (PCB) substrate, ceramic substrate, or any suitable type of substrate. In this case of a TMR stack, it will be appreciated that the TMR film within the stack will also comprise a tunnel barrier layer positioned between the reference layer and the sensing layer.

At step 904, the blanket TMR stack will be patterned into two or more arrays of sensing elements, for example, using ion beam etching techniques, each array being patterned such that the sensing elements within a given array have a particular aspect ratio. The arrays of sensing elements will also be patterned such that an even number of sensing elements is provided, each pair of sensing elements being connected in series by a bottom electrode.

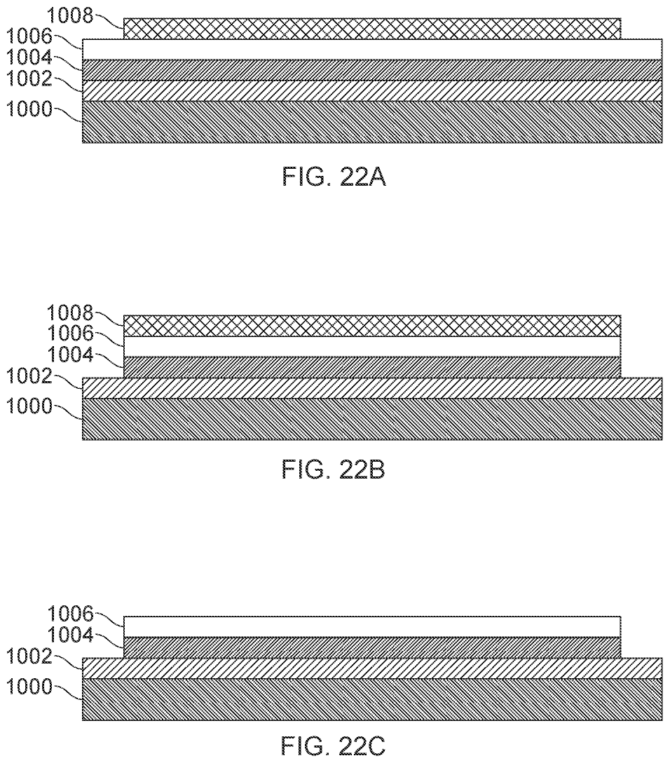

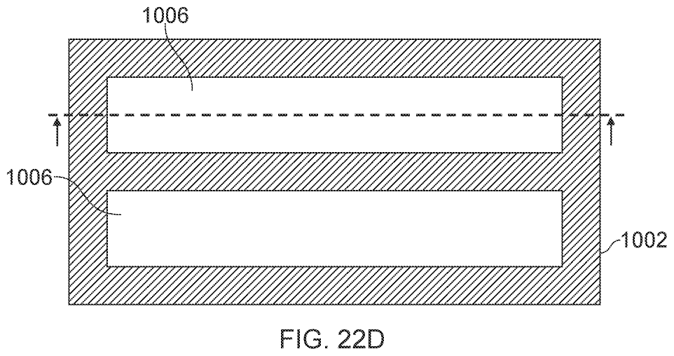

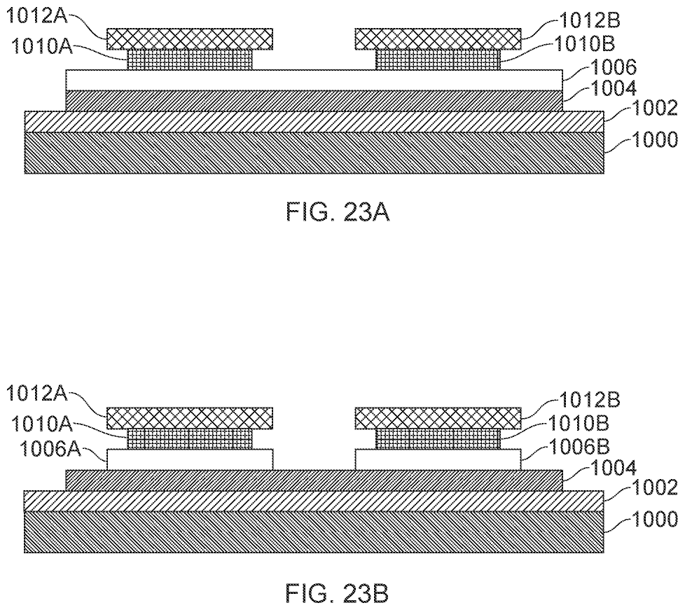

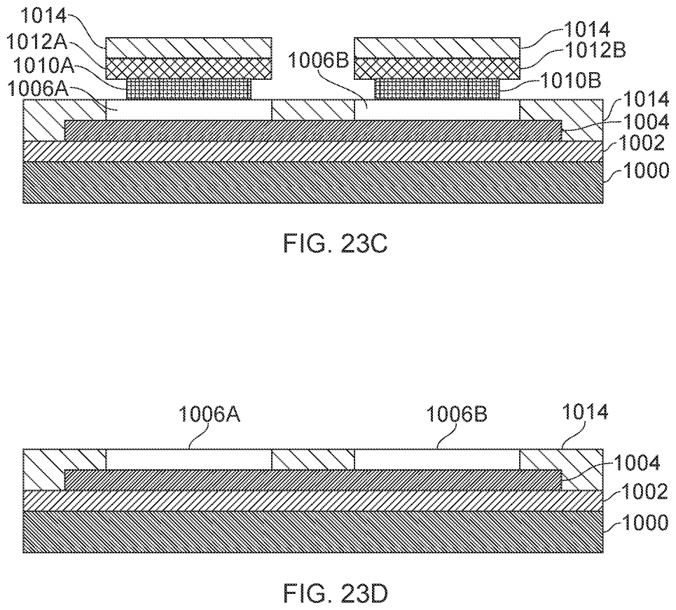

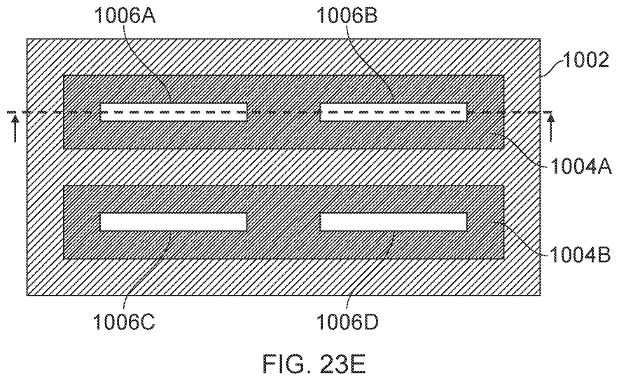

The process of patterning of the TMR stack is shown in more detail in FIGS. 22-23. FIGS. 22A-D illustrate the method by which the bottom electrode of the TMR stack is patterned. FIG. 22D shows the blanket TMR stack comprising a substrate 1000 at the base (typically formed from silicon), followed by layer of intermetal dielectric (IMD) oxide 1002, such as silicon oxide, a bottom electrode 1004, and a TMR film 1006 (i.e., comprising the reference layers, the tunnel barrier layer and the sensing layers). To begin the process, a photoresist 1008 is applied to the stack, which is then used to etch (e.g., using ion beam etching) through a portion of the TMR film 1006 and the bottom electrode 1004, as shown in FIG. 22B. The photoresist material 1008 is then removed, as shown in FIGS. 22C-D. In this respect, FIG. 22D shows a top view wherein two lengths of TMR film 1006 (with a bottom electrode 1004 below) have been left on the substrate 1002.

FIGS. 23A-E illustrate the method by which the TMR film 1006 is patterned into pairs of sensing elements. As shown in FIG. 23A, a pair of TMR sensing elements are formed by first applying a lift-off coating 1010A-B and a photoresist coating 1012A-B. As shown in FIG. 23B, the TMR film 1006 is then etched to leave two TMR sensing elements defined by portions 1006A-B.

In the next step 906, illustrated further by FIG. 23C, a layer of passivation material 1014 is deposited for protecting the TMR elements 1006A-B and ensuring that the side walls do not short circuit. As shown in FIG. 23D, the lift-off coating 1010A-B is then used to lift-off the photoresist coating 1012A-B and passivation material 1014 thereon. In this respect, FIG. 23E shows a top view wherein two arrays of sensing elements, 1006A-B and 1006C-D respectively (each with a bottom electrode 1004A-B below), have been left on the substrate 1002. Whilst shown as having the same size, it will of course be appreciated that the sensing elements of the two arrays, 1006A-B and 1006C-D, may be provided with different aspect ratios in accordance with the present disclosure to thereby provide different sensitivities.

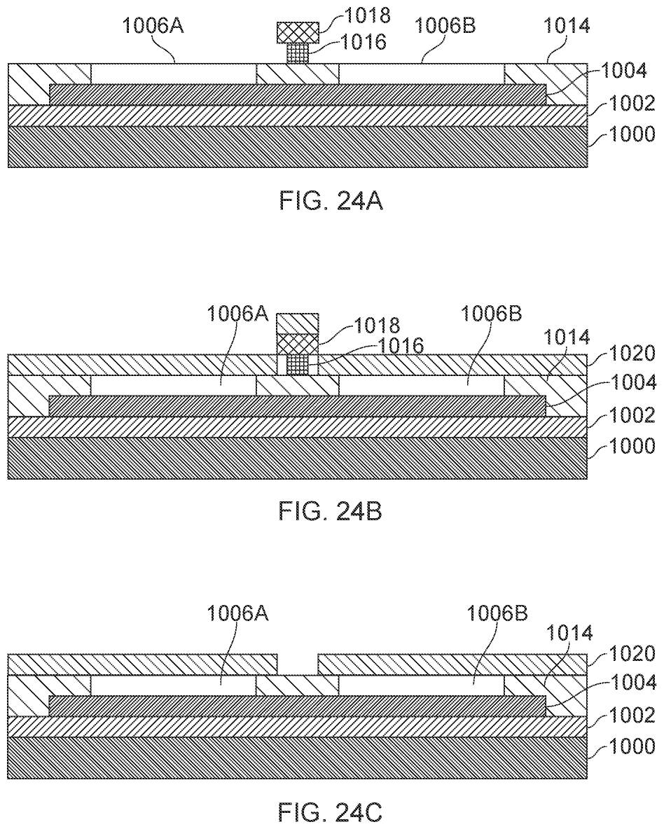

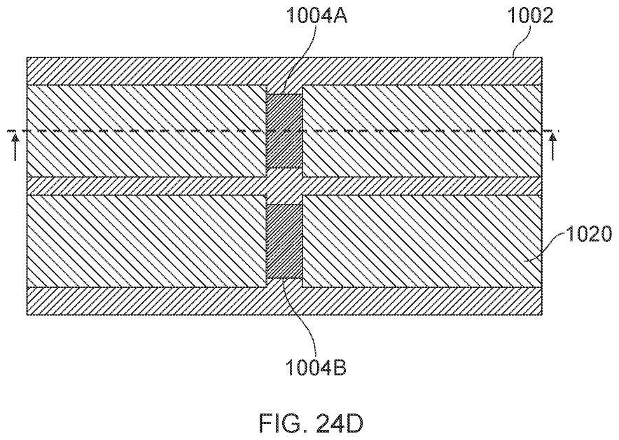

At step 908, illustrated further by FIGS. 24A-D, metal contacts are formed over the TMR sensing elements 1006A-B, thereby providing a top electrode. As shown by FIG. 24A, a lift-off coating 1016 and a photoresist coating 1018 are first applied. A metal layer 1020 (such as tantalum or gold) is deposited over the stack, as shown in FIG. 24B, to thereby form the metal contacts. As shown in FIG. 24C, the lift-off coating 1016 is then used to lift-off the photoresist coating 1018 and the metal 1020 thereon. FIG. 24D thus shows the top view, wherein the metal contacts 1020 are now formed over the sensing elements.

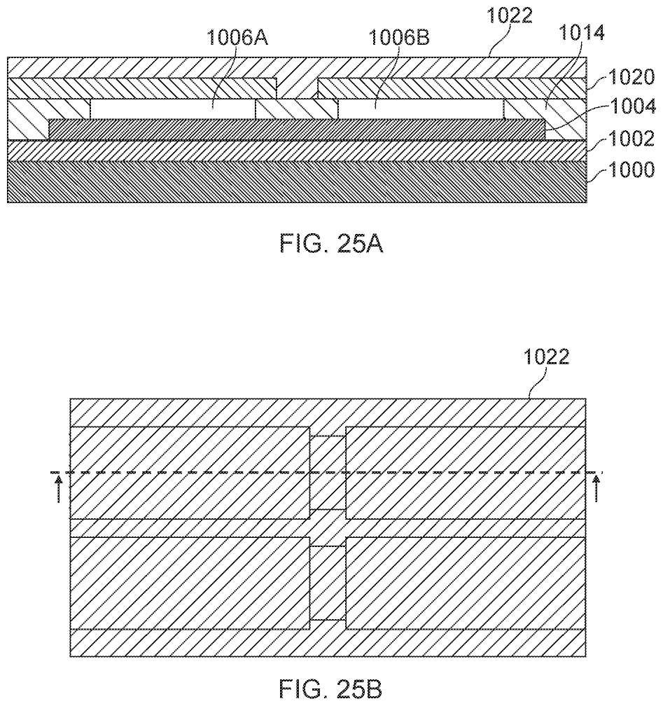

At step 910, further illustrated by FIGS. 25A-B, a layer of passivation material 1022 is deposited over the entire substrate.

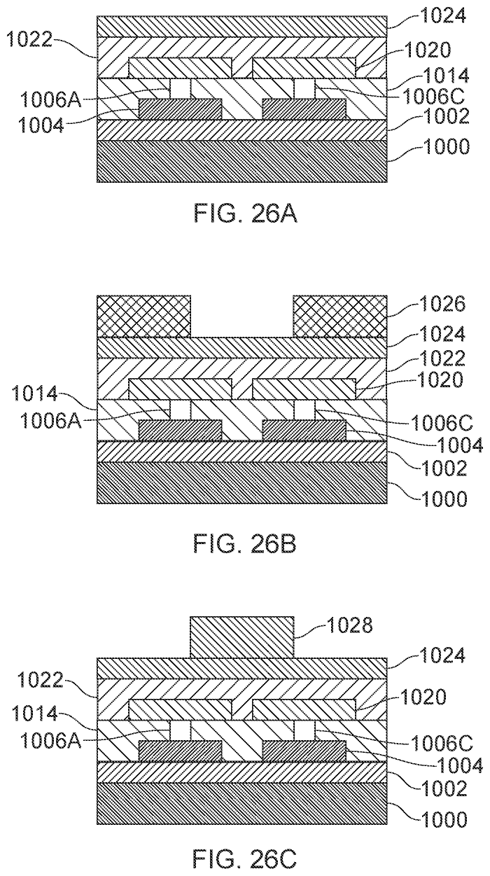

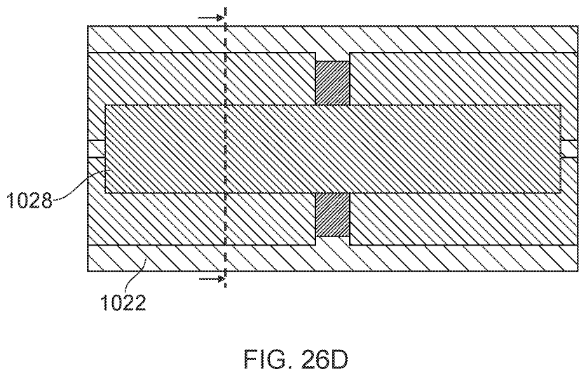

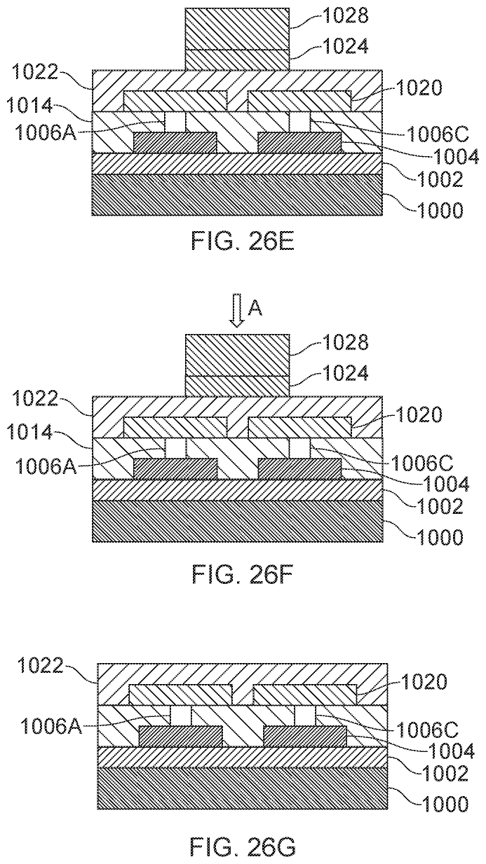

At step 912, magnetic annealing of both the reference layers and the sensing layers in order to set the magnetisation directions thereof. FIGS. 26A-G illustrate a method by which the reference layer may be magnetically annealed using a flux concentrator. FIGS. 26A-C and 26E-G show a side view, such that each of the TMR sensing elements 1006 shown are one element in their respective array. First, as shown in FIG. 26A, a seed layer 1024 is deposited. A photoresist coating 1026 is then applied, as shown in FIG. 26B, such that only a portion of the seed layer 1024 is exposed. In the exposed portion, a flux concentrator 1028 is plated and the photoresist coating 1026 is removed, as shown in FIG. 26C. The flux concentrator 1028 is positioned such that it lies between two arrays of sensing elements (the first sensing elements 1006A, 1006C being shown). FIG. 26D provides a top view showing the plated flux concentrator 1028.

As shown in FIG. 26E, the seed layer 1024 is etched such that the only portion remaining is that directly below the flux concentrator 1028. As shown in FIG. 26F, an out-of-plane magnetic field, as illustrated by arrow A, is applied to magnetically anneal the reference layer, such that the magnetisation directions are fixed in a particular direction. By placing the flux concentrator 1028 between two arrays of sensing elements 1006A, 1006C, the reference layers of the sensing elements 1006A, 1006C of each array will be magnetised in opposing directions. Therefore, the stack may be rotated relative to the out-of-plane magnetic field to ensure that the magnetisation direction of the array comprising the sensing elements with the lowest sensitivity is set in a particular direction. Once this has been completed, the seed layer 1024 and flux concentrator 1028 are removed (e.g., by etching), as shown in FIG. 26G. Of course, it will also be appreciated that the magnetisation direction of the reference layer (i.e., the reference direction) may be set using a number of different methods.

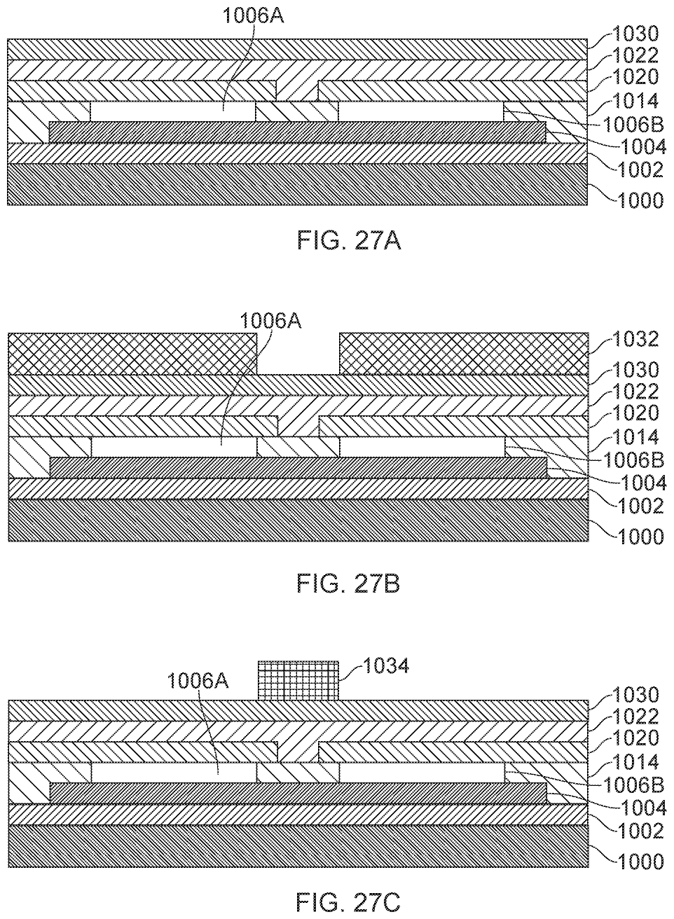

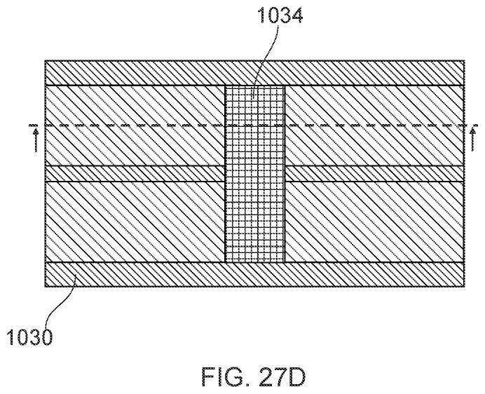

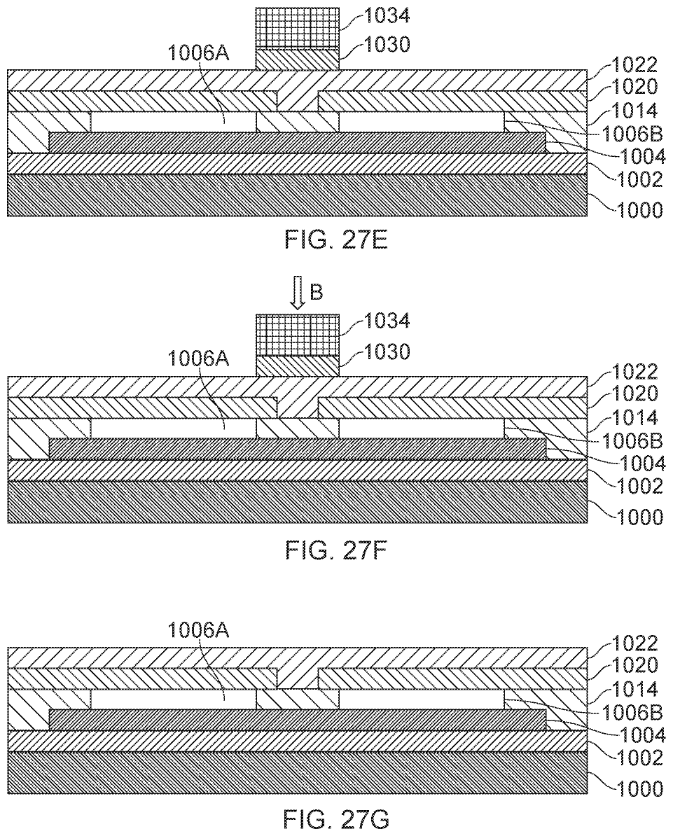

FIGS. 27A-G illustrate a method by which the sensing layers may be magnetically annealed using a flux concentrator. First, as shown in FIG. 27A, a seed layer 1030 is deposited. A photoresist coating 1032 is then applied, as shown in FIG. 27B, such that only a portion of the seed layer 1030 is exposed. In the exposed portion, a flux concentrator 1034 is plated and the photoresist coating 1032 is removed, as shown in FIG. 27C. The flux concentrator 1034 is positioned such that it lies between respective pairs of sensing elements 1006A-B. FIG. 27D provides a top view showing the plated flux concentrator 1034.

As shown in FIG. 27E, the seed layer 1030 is etched such that the only portion remaining is that directly below the flux concentrator 1034. As shown in FIG. 27F, an out-of-plane magnetic field, as shown by arrow B, is applied to magnetically anneal the sensing layers, such that the magnetisation directions are fixed in a particular direction. By placing the flux concentrator 1034 between pairs of sensing elements 1006A-B, the sensing layers of each pair of sensing elements 1006A-B will be softly pinned in antiparallel directions, thus providing the differential soft pinned sensing layers. Once this has been completed, the seed layer 1030 and flux concentrator 1034 are removed (e.g., by etching), as shown in FIG. 27G.

At step 914, additional coil biasing may be performed, for example, by plating the surface with a metal material (not shown). In this respect, an electromagnet may be fabricated to increase the biasing field in order to increase the cross-field range (i.e., the amount of cross-field that can be attenuated), or alternatively, the electromagnet may be used to generate the biasing field to thereby provide the differential biasing of the sensing layer. Similarly, a further layer of passivation material (not shown) may also be deposited at 916.

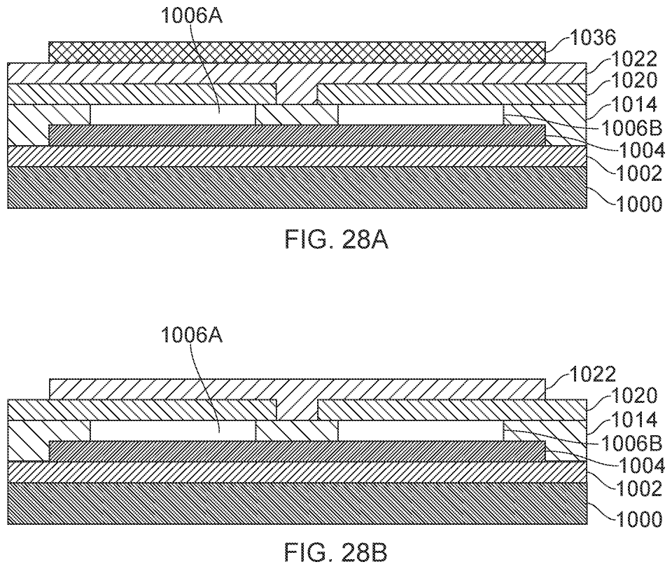

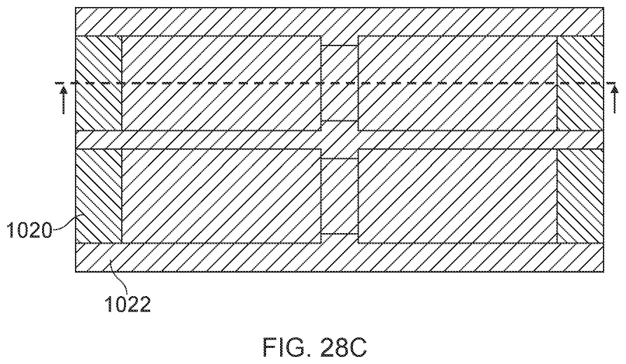

Finally, at step 918, and further illustrated by FIG. 28C, bond pads are patterned into the sensing device, for example, using a wet etch, for electrically connecting the TMR sensing device. As shown in FIG. 28A, a photoresist coating 1036 is applied, exposing only the portions of the passivation layer 1022 to be removed. As shown, in FIG. 28B, the passivation layer 1022 is etched to expose portions of the metal contacts 1020 and the photoresist coating 1036 removed. This is further illustrated by the top view shown in FIG. 28C, wherein portions of the metal contacts 1020 are exposed as bond pads for electrically connecting the TMR sensing device.

Various modifications, whether by way of addition, deletion and/or substitution, may be made to all of the above described embodiments to provide further embodiments, any and/or all of which are intended to be encompassed by the appended claims.

### Applications

Any of the principles and advantages discussed herein can be applied to other systems, not just to the systems described above. Some embodiments can include a subset of features and/or advantages set forth herein. The elements and operations of the various embodiments described above can be combined to provide further embodiments. The acts of the methods discussed herein can be performed in any order as appropriate. Moreover, the acts of the methods discussed herein can be performed serially or in parallel, as appropriate. While circuits are illustrated in particular arrangements, other equivalent arrangements are possible.

Any of the principles and advantages discussed herein can be implemented in connection with any other systems, apparatus, or methods that benefit could from any of the teachings herein. For instance, any of the principles and advantages discussed herein can be implemented in connection with any devices with a need for shielding stray magnetic fields from a magnetic sensor system comprising a magnetic sensor.

Aspects of this disclosure can be implemented in various electronic devices or systems. For instance, phase correction methods and sensors implemented in accordance with any of the principles and advantages discussed herein can be included in various electronic devices and/or in various applications. Examples of the electronic devices and applications can include, but are not limited to, servos, robotics, aircraft, submarines, toothbrushes, biomedical sensing devices, and parts of the consumer electronic products such as semiconductor die and/or packaged modules, electronic test equipment, etc. Further, the electronic devices can include unfinished products, including those for industrial, automotive, and/or medical applications.

Unless the context clearly requires otherwise, throughout the description and the claims, the words “comprise,”“comprising,”“include,”“including,” and the like are to be construed in an inclusive sense, as opposed to an exclusive or exhaustive sense; that is to say, in the sense of “including, but not limited to.” The words “coupled” or “connected”, as generally used herein, refer to two or more elements that may be either directly connected, or connected by way of one or more intermediate elements. Thus, although the various schematics shown in the figures depict example arrangements of elements and components, additional intervening elements, devices, features, or components may be present in an actual embodiment (assuming that the functionality of the depicted circuits is not adversely affected). The words “based on” as used herein are generally intended to encompass being “based solely on” and being “based at least partly on.” Additionally, the words “herein,”“above,”“below,” and words of similar import, when used in this application, shall refer to this application as a whole and not to any particular portions of this application. Where the context permits, words in the Detailed Description using the singular or plural number may also include the plural or singular number, respectively. The words “or” in reference to a list of two or more items, is intended to cover all of the following interpretations of the word: any of the items in the list, all of the items in the list, and any combination of the items in the list. All numerical values or distances provided herein are intended to include similar values within a measurement error.

While certain embodiments have been described, these embodiments have been presented by way of example only and are not intended to limit the scope of the disclosure. Indeed, the novel apparatus, systems, and methods described herein may be embodied in a variety of other forms. Furthermore, various omissions, substitutions and changes in the form of the methods and systems described herein may be made without departing from the spirit of the disclosure.

1. A magnetoresistive field sensor system, comprising:
one or more magnetoresistive field sensors, each magnetoresistive field sensor comprising:
a first sensor array of magnetoresistive sensing elements having a first sensitivity, wherein each of the magnetoresistive elements in the first array comprise a sensing layer to which a first biasing field is applied, and a reference structure magnetised in a first reference magnetisation direction; and
at least a second sensor array of magnetoresistive sensing elements having a second sensitivity, the second sensitivity being higher than the first sensitivity, wherein each of the magnetoresistive elements in the second array comprise a sensing layer to which a second biasing field is applied, and a reference structure magnetised in a second reference magnetisation direction, the second reference magnetisation direction being opposite to the first reference magnetisation direction.

2. A magnetoresistive field sensor system according to claim 1, wherein the first sensor array comprises magnetoresistive elements having a first aspect ratio to thereby provide the first sensitivity, and the second sensor array comprises magnetoresistive elements having a second aspect ratio to thereby provide the second sensitivity.

3. A magnetoresistive field sensor system according to claim 1, wherein the first sensor array comprises a first number of magnetoresistive sensing elements and the second sensor array comprises a second number of magnetoresistive sensing elements.

4. A magnetoresistive field sensor system according to claim 3, wherein the first number of magnetoresistive sensing elements is different to the second number of magnetoresistive sensing elements.

5. A magnetoresistive field sensor system according to claim 3, wherein the first and second number of sensing elements is determined by a respective weighted value, wherein each weighted value is indicative of the percentage of a sensor output provided by the respective array.

6. A magnetoresistive field sensor system according to claim 1, wherein the first and second biasing field are induced by differential sensing layer bias.

7. A magnetoresistive field sensor system according to claim 6, wherein the first and second sensor arrays comprise respective pairs of magnetoresistive sensing elements with softly pinned antiparallel sensing layers.

8. A magnetoresistive field sensor system according to claim 7, wherein the sensing layers of the respective pairs of magnetoresistive sensing elements are softly pinned by an antiferromagnetic layer.

9. A magnetoresistive field sensor system according to claim 1, wherein the first and second biasing fields are induced by one or more permanent magnets or an electromagnet.

10. A magnetoresistive field sensor system according to claim 1, wherein each magnetoresistive field sensor further comprises a third array of magnetoresistive sensing elements having a third sensitivity, the third sensitivity being higher than the second sensitivity, wherein each of the magnetoresistive elements in the third array comprise a sensing layer to which a third biasing field is applied, a reference structure magnetised in the second reference magnetisation direction.

11. A magnetoresistive field sensor system according to claim 10, wherein the third sensor array comprises magnetoresistive elements having a third aspect ratio to thereby provide the third sensitivity.

12. A magnetoresistive field sensor system according to claim 10, wherein the third biasing field is induced by differential sensing layer bias.

13. A magnetoresistive field sensor system according to claim 12, wherein the third sensor array comprises respective pairs of magnetoresistive sensing elements with softly pinned antiparallel sensing layers.

14. A magnetoresistive field sensor system according to claim 13, wherein the sensing layers of respective pairs of magnetoresistive sensing elements are softly pinned by an antiferromagnetic layer.

15. A magnetoresistive field sensor system according to claim 10, wherein the third biasing field is induced by one or more permanent magnets or an electromagnet.

16. A magnetoresistive field sensor system according to claim 1, wherein the first reference magnetisation direction defines the sensing direction of the one or more magnetoresistive field sensors.

17. A magnetoresistive field sensor system according to claim 1, wherein the magnetoresistive field sensor system comprises a first set of magnetoresistive field sensors connected in a first Wheatstone bridge arrangement.

18. A magnetoresistive field sensor system according to claim 17, further comprising a second set of magnetoresistive field sensors connected in a second Wheatstone bridge arrangement, wherein the second Wheatstone bridge arrangement is rotated 90° relative to the first Wheatstone bridge arrangement.

19. A magnetoresistive field sensor system according to claim 1, wherein the magnetoresistive sensing elements are tunnel magnetoresistive sensing elements or giant magnetoresistive sensing elements.
